(19) United States
(12) Patent Application Publication
(10) Pub. No.: US 2026/0231412 A1
(43) Pub. Date: Aug. 6, 2026

(54) MEMORY DEVICE

(71) Applicant: Kioxia Corporation, Tokyo (JP)

(72) Inventor: Yusuke OKUMURA, Yokkaichi (JP)

(73) Assignee: Kioxia Corporation, Tokyo (JP)

(21) Appl. No.: 19/239,067

(22) Filed: Jun. 16, 2025

(30) Foreign Application Priority Data
Feb. 6, 2025 (JP) 2025-018632

(51) Int. Cl. H10B 43/27; H01L 23/00; H01L 25/065; H01L 25/18; H10B 43/10; H10B 80/00

(52) U.S. Cl. CPC H10B 43/27; H10B 43/10; H10B 80/00; H10W 90/00; H10W 90/792

(57) ABSTRACT

A memory device includes: first wiring layers aligned apart from each other in a direction; second, third, and fourth wiring layers aligned in this order and apart from each other in the direction without interposing another wiring layer; and a memory pillar extending in the direction and including portions respectively intersecting with the first, second, and third wiring layers to function as memory cells. The first, second, and third wiring layers include first, second, and third terrace portions, respectively, that are thickened. Between each of the first terrace portions and each of other first terrace portions adjacent to the each of the first terrace portions, at least one wiring layer is provided. The third terrace portion is adjacent to the second terrace portion in the direction. The third wiring layer includes a not-thickened portion at a boundary between the third and second terrace portions.

### CROSS-REFERENCE TO RELATED APPLICATIONS

This application is based upon and claims the benefit of priority from Japanese Patent Application No. 2025-018632, filed Feb. 6, 2025, the entire contents of which are incorporated herein by reference.

### FIELD

Embodiments described herein relate generally to a memory device.

### BACKGROUND

A NAND flash memory is known as a memory device capable of storing data in a non-volatile manner. In a memory device such as a NAND flash memory, a three-dimensional memory structure is adopted for high integration and large capacity.

### BRIEF DESCRIPTION OF THE DRAWINGS

FIG. 1 is a block diagram illustrating an example of a configuration of a memory system including a memory device according to a first embodiment.

FIG. 2 is a circuit diagram illustrating an example of a circuit configuration of a memory cell array included in the memory device according to the first embodiment.

FIG. 3 is a plan view illustrating an example of a planar layout of the memory cell array included in the memory device according to the first embodiment.

FIG. 4 is a plan view illustrating an example of a planar layout in a region IV of FIG. 3 in the memory cell array included in the memory device according to the first embodiment.

FIG. 5 is a cross-sectional view taken along a line V-V of FIG. 4, illustrating an example of a cross-sectional structure of the memory cell array included in the memory device according to the first embodiment.

FIG. 6 is a cross-sectional view taken along a line VI-VI of FIG. 4, illustrating an example of a cross-sectional structure of the memory cell array included in the memory device according to the first embodiment.

FIG. 7 is a cross-sectional view taken along a line VII-VII of FIG. 5, illustrating an example of a cross-sectional structure of a memory pillar included in the memory cell array according to the first embodiment.

FIG. 8 is a perspective view illustrating an outline of a bonding structure of the memory device according to the first embodiment.

FIG. 9 is a cross-sectional view illustrating an example of a cross-sectional structure of a bonding pad included in the memory device according to the first embodiment.

FIG. 10 is a cross-sectional view illustrating an example of a cross-sectional structure of the memory device according to the first embodiment.

FIG. 11 is a plan view illustrating an example of a planar layout in a process of manufacturing the memory device according to the first embodiment.

FIG. 12 is a cross-sectional view illustrating an example of a cross-sectional structure in the process of manufacturing the memory device according to the first embodiment.

FIG. 13 is a plan view illustrating an example of a planar layout in the process of manufacturing the memory device according to the first embodiment.

FIG. 14 is a cross-sectional view illustrating an example of a cross-sectional structure in the process of manufacturing the memory device according to the first embodiment.

FIG. 15 is a plan view illustrating an example of a planar layout in the process of manufacturing the memory device according to the first embodiment.

FIG. 16 is a cross-sectional view illustrating an example of a cross-sectional structure in the process of manufacturing the memory device according to the first embodiment.

FIG. 17 is a plan view illustrating an example of a planar layout in the process of manufacturing the memory device according to the first embodiment.

FIG. 18 is a cross-sectional view illustrating an example of a cross-sectional structure in the process of manufacturing the memory device according to the first embodiment.

FIG. 19 is a plan view illustrating an example of a planar layout in the process of manufacturing the memory device according to the first embodiment.

FIG. 20 is a cross-sectional view illustrating an example of a cross-sectional structure in the process of manufacturing the memory device according to the first embodiment.

FIG. 21 is a plan view illustrating an example of a planar layout in the process of manufacturing the memory device according to the first embodiment.

FIG. 22 is a cross-sectional view illustrating an example of a cross-sectional structure in the process of manufacturing the memory device according to the first embodiment.

FIG. 23 is a plan view illustrating an example of a planar layout in the process of manufacturing the memory device according to the first embodiment.

FIG. 24 is a cross-sectional view illustrating an example of a cross-sectional structure in the process of manufacturing the memory device according to the first embodiment.

FIG. 25 is a cross-sectional view illustrating an example of a cross-sectional structure in the process of manufacturing the memory device according to the first embodiment.

FIG. 26 is a cross-sectional view illustrating an example of a cross-sectional structure in the process of manufacturing the memory device according to the first embodiment.

FIG. 27 is a cross-sectional view illustrating an example of a cross-sectional structure in the process of manufacturing the memory device according to the first embodiment.

FIG. 28 is a cross-sectional view illustrating an example of a cross-sectional structure in the process of manufacturing the memory device according to the first embodiment.

FIG. 29 is a cross-sectional view illustrating an example of a cross-sectional structure in the process of manufacturing the memory device according to the first embodiment.

FIG. 30 is a cross-sectional view illustrating an example of a cross-sectional structure in the process of manufacturing the memory device according to the first embodiment.

FIG. 31 is a cross-sectional view illustrating an example of a cross-sectional structure in the process of manufacturing the memory device according to the first embodiment.

FIG. 32 is a cross-sectional view illustrating an example of a cross-sectional structure in the process of manufacturing the memory device according to the first embodiment.

FIG. 33 is a cross-sectional view illustrating an example of a cross-sectional structure in the process of manufacturing the memory device according to the first embodiment.

FIG. 34 is a cross-sectional view illustrating an example of a cross-sectional structure in the process of manufacturing the memory device according to the first embodiment.

FIG. 35 is a cross-sectional view illustrating an example of a cross-sectional structure in the process of manufacturing the memory device according to the first embodiment.

FIG. 36 is a plan view illustrating an example of a planar layout of a memory cell array included in a memory device according to a second embodiment.

FIG. 37 is a cross-sectional view taken along a line XXXVII-XXXVII of FIG. 36, illustrating an example of a cross-sectional structure of the memory cell array included in the memory device according to the second embodiment.

FIG. 38 is a cross-sectional view taken along a line XXXVIII-XXXVIII in FIG. 36, illustrating an example of a cross-sectional structure of the memory cell array included in the memory device according to the second embodiment.

FIG. 39 is a plan view illustrating an example of a planar layout in a process of manufacturing the memory device according to the second embodiment.

FIG. 40 is a plan view illustrating an example of a planar layout in the process of manufacturing the memory device according to the second embodiment.

FIG. 41 is a plan view illustrating an example of a planar layout in the process of manufacturing the memory device according to the second embodiment.

FIG. 42 is a plan view illustrating an example of a planar layout in the process of manufacturing the memory device according to the second embodiment.

FIG. 43 is a plan view illustrating an example of a planar layout of a memory cell array included in a memory device according to a third embodiment.

FIG. 44 is a cross-sectional view taken along a line XLIV-XLIV of FIG. 43, illustrating an example of a cross-sectional structure of the memory cell array included in the memory device according to the third embodiment.

FIG. 45 is a cross-sectional view taken along a line XLV-XLV of FIG. 43, illustrating an example of a cross-sectional structure of the memory cell array included in the memory device according to the third embodiment.

FIG. 46 is a plan view illustrating an example of a planar layout in a process of manufacturing the memory device according to the third embodiment.

FIG. 47 is a plan view illustrating an example of a planar layout in the process of manufacturing the memory device according to the third embodiment.

FIG. 48 is a plan view illustrating an example of a planar layout in the process of manufacturing the memory device according to the third embodiment.

FIG. 49 is a plan view illustrating an example of a planar layout in the process of manufacturing the memory device according to the third embodiment.

FIG. 50 is a plan view illustrating an example of a planar layout in the process of manufacturing the memory device according to the third embodiment.

FIG. 51 is a plan view illustrating an example of a planar layout in the process of manufacturing the memory device according to the third embodiment.

FIG. 52 is a plan view illustrating an example of a planar layout of a memory cell array included in a memory device according to a fourth embodiment.

FIG. 53 is a cross-sectional view taken along a line LIII-LIII of FIG. 52, illustrating an example of a cross-sectional structure of the memory cell array included in the memory device according to the fourth embodiment.

FIG. 54 is a plan view illustrating an example of a planar layout in a process of manufacturing the memory device according to the fourth embodiment.

FIG. 55 is a plan view illustrating an example of a planar layout in the process of manufacturing the memory device according to the fourth embodiment.

FIG. 56 is a plan view illustrating an example of a planar layout in the process of manufacturing the memory device according to the fourth embodiment.

FIG. 57 is a plan view illustrating an example of a planar layout in the process of manufacturing the memory device according to the fourth embodiment.

FIG. 58 is a cross-sectional view illustrating an example of a cross-sectional structure of a memory cell array included in a memory device according to a modification.

FIG. 59 is a cross-sectional view illustrating an example of a cross-sectional structure in a region LIX of

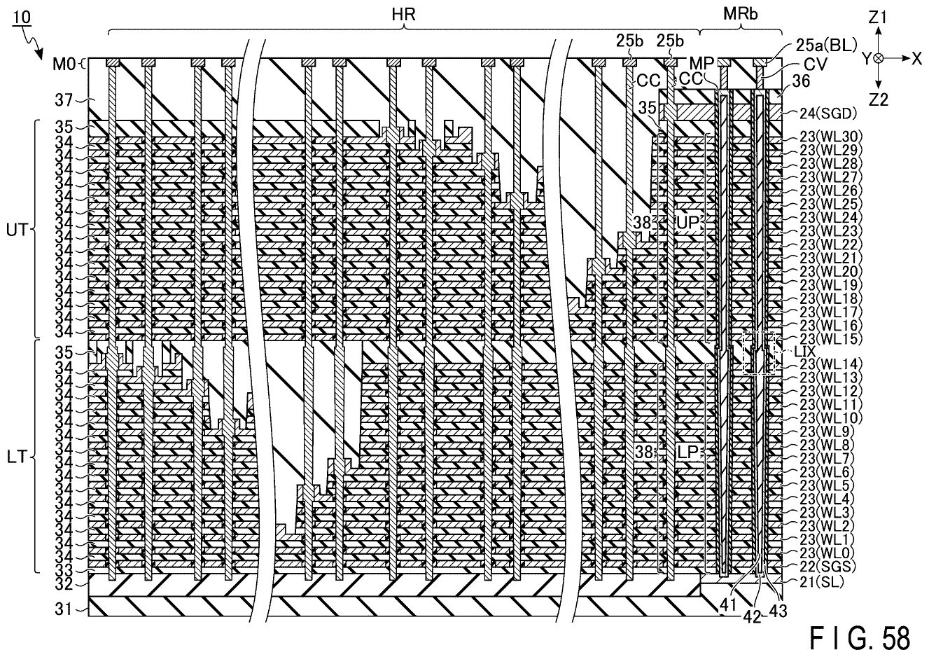

FIG. 58 among memory pillars included in the memory cell array according to the modification.

### DETAILED DESCRIPTION

In general, according to one embodiment, a memory device includes: a plurality of first wiring layers that are aligned apart from each other in a first direction; a second wiring layer, a third wiring layer, and a fourth wiring layer that are aligned in the first direction apart from the first wiring layers and are aligned in this order and apart from each other in the first direction without interposing another wiring layer; and a first memory pillar that extends in the first direction and includes portions respectively intersecting with the first wiring layers, the second wiring layer, and the third wiring layer to function as memory cells. The first wiring layers, the second wiring layer, and the third wiring layer include a plurality of first terrace portions, a second terrace portion, and a third terrace portion, respectively, that are thickened. Between each of the first terrace portions and each of a plurality of other first terrace portions adjacent to the each of the first terrace portions as viewed in the first direction, at least one wiring layer other than two wiring layers having two adjacent first terrace portions is provided. The third terrace portion is adjacent to the second terrace portion as viewed in the first direction. The third wiring layer includes a portion that is not thickened, at a boundary between the third terrace portion and the second terrace portion.

Hereinafter, embodiments will be described with reference to the drawings. Dimensions and ratios of the drawings are not necessarily the same as actual ones.

In the following description, components having substantially the same functions and configurations are denoted by the same reference numerals. In a case where the components having similar configurations are particularly distinguished from each other, different characters or numbers may be added to the end of the same reference numeral.

### 1. First Embodiment

### 1.1 Configuration

### 1.1.1 Configuration of Memory System

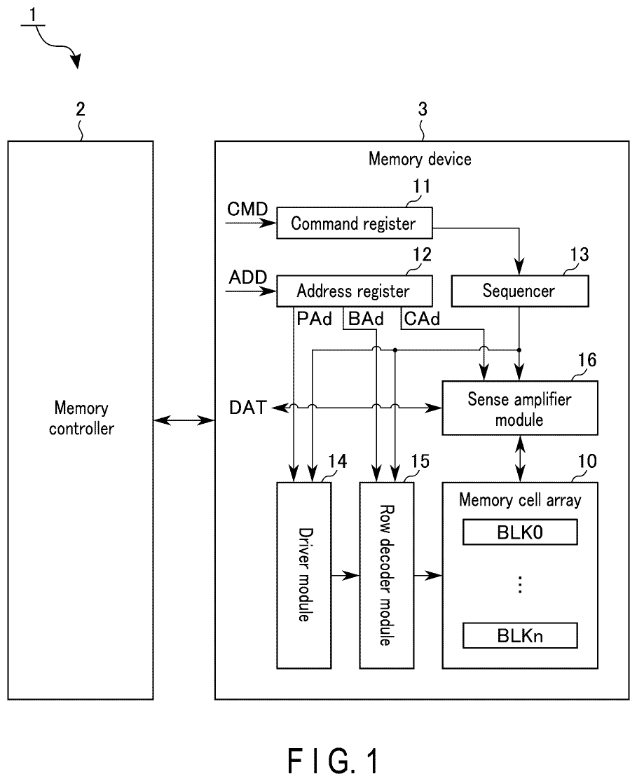

FIG. 1 is a block diagram illustrating an example of a configuration of a memory system including a memory device according to a first embodiment. A memory system 1 is a storage device configured to be connected to an external host (not illustrated). The memory system 1 is, for example, a memory card such as an SD™ card, a universal flash storage (UFS), or a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data, which is requested by the host to write, to the memory device 3. In addition, the memory controller 2 reads data, which is requested by the host to read, from the memory device 3 and transmits the data to the host.

The memory device 3 is a non-volatile memory. The memory device 3 is, for example, a NAND flash memory. The memory device 3 stores data in a non-volatile manner.

Communication between the memory controller 2 and the memory device 3 conforms to, for example, a single data rate (SDR) interface, a toggle double data rate (DDR) interface, or an open NAND flash interface (ONFI).

### 1.1.2 Configuration of Memory Device

With reference to the block diagram illustrated in FIG. 1, an internal configuration of the memory device according to the first embodiment will be described. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer that is equal to or greater than one). The number of blocks BLK included in the memory cell array 10 may be one. The block BLK is a set of a plurality of memory cells. The block BLK is used, for example, as a data erasing unit. A plurality of bit lines and a plurality of word lines are provided in the memory cell array 10. Each memory cell is associated with a bit line and a word line, for example. A detailed configuration of the memory cell array 10 will be described later.

The command register 11 stores a command CMD received by the memory device 3 from the memory controller 2. The command CMD includes, for example, an order for causing the sequencer 13 to execute a read operation, a write operation, an erase operation, and the like.

The address register 12 stores address information ADD received by the memory device 3 from the memory controller 2. The address information ADD includes, for example, a block address BAd, a page address PAd, and a column address CAd. For example, the block address BAd, the page address PAd, and the column address CAd are used to select a block BLK, a word line, and a bit line, respectively.

The sequencer 13 controls the entire operation of the memory device 3. For example, the sequencer 13 controls the driver module 14, the row decoder module 15, the sense amplifier module 16, and the like based on the command CMD stored in the command register 11 to execute the read operation, write operation, erase operation, and the like.

The driver module 14 generates a voltage used in the read operation, write operation, erase operation, and the like. Then, the driver module 14 applies the generated voltage to a signal line corresponding to a selected word line based on, for example, the page address PAd stored in the address register 12.

The row decoder module 15 selects a block BLK in the corresponding memory cell array 10 based on the block address BAd stored in the address register 12. Then, the row decoder module 15 transfers, for example, the voltage applied to the signal line corresponding to the selected word line to the selected word line in the selected block BLK.

In the write operation, the sense amplifier module 16 applies a desired voltage to each bit line according to write data DAT received from the memory controller 2. In addition, in the read operation, the sense amplifier module 16 determines the data stored in the memory cell based on the voltage of the bit line, and transfers the determination result to the memory controller 2 as read data DAT.

### 1.1.3 Memory Cell Array

Next, a configuration of a memory cell array included in the memory device according to the first embodiment will be described.

### 1.1.3.1 Circuit Configuration

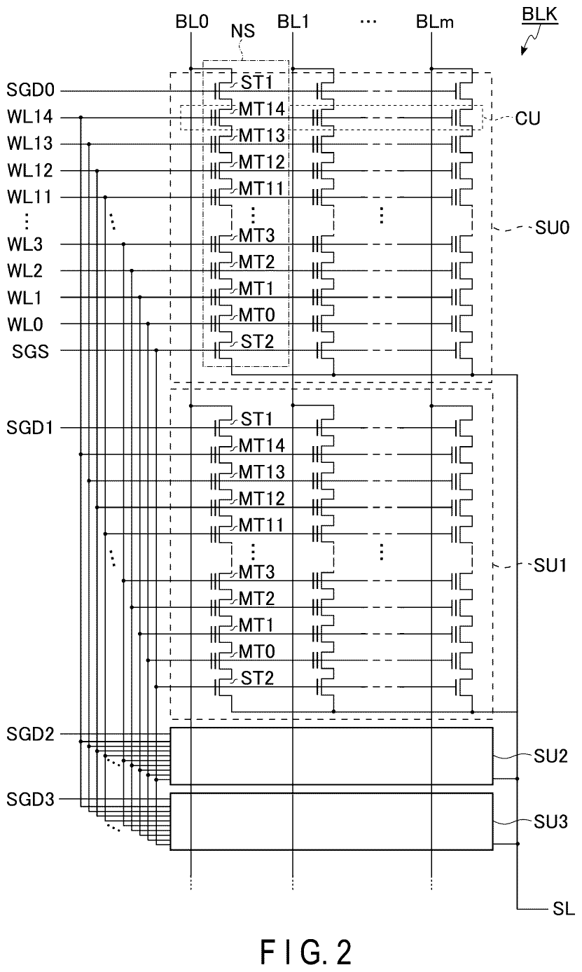

FIG. 2 is a circuit diagram illustrating an example of a circuit configuration of the memory cell array included in the memory device according to the first embodiment. FIG. 2 illustrates a block BLK of the blocks BLK included in the memory cell array 10. As illustrated in FIG. 2, the block BLK includes, for example, four string units SU0 to SU3.

Each string unit SU includes a plurality of NAND strings NS associated with bit lines BL0 to BLm (m is an integer that is equal to or greater than one), respectively. The number of the bit lines BL may be one. Each NAND string NS includes, for example, memory cell transistors MT0 to MT14 and select transistors ST1 and ST2. Each memory cell transistor MT includes a control gate and a charge storage film, and stores data in a nonvolatile manner. Each of the select transistors ST1 and ST2 is used to select the string unit SU during various operations.

In each NAND string NS, the memory cell transistors MT0 to MT14 are connected in series. A drain of the select transistor ST1 is connected to an associated bit line BL. A source of the select transistor ST1 is connected to one end of the memory cell transistors MT0 to MT14 connected in series. A drain of the select transistor ST2 is connected to the other end of the memory cell transistors MT0 to MT14 connected in series. A source of the select transistor ST2 is connected to the source line SL.

In a same block BLK, the control gates of the memory cell transistors MT0 to MT14 are connected to the word lines WL0 to WL14, respectively. Gates of the select transistors ST1 in the string units SU0 to SU3 are connected to select gate lines SGD0 to SGD3, respectively. Gates of the select transistors ST2 are connected to the select gate line SGS.

Different column addresses are allocated to the bit lines BL0 to BLm. Each bit line BL is shared by the NAND strings NS to which the same column address is allocated among the blocks BLK. Each of the word lines WL0 to WL14 is provided for each block BLK. The source line SL is shared among the blocks BLK, for example.

A set of the memory cell transistors MT connected to the common word line WL in a string unit SU is referred to as, for example, a cell unit CU. For example, the storage capacity of the cell unit CU including the memory cell transistor MT each storing one-bit data is defined as “one-page data”. The cell unit CU may have a storage capacity of two-page data or more according to the number of bits of data stored in the memory cell transistor MT.

Note that the circuit configuration of the memory cell array 10 included in the memory device 3 according to the first embodiment is not limited to the configuration described above. For example, the number of string units SU included in each block BLK can be designed to an any number. The number of the memory cell transistors MT and the select transistors ST1 and ST2 included in each NAND string NS can be designed to any number.

### 1.1.3.2 Planar Layout

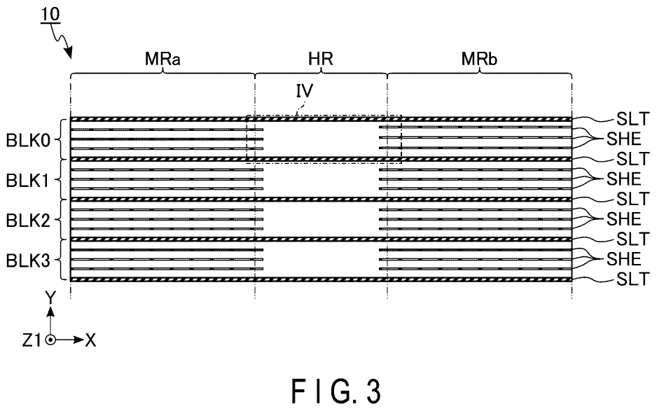

FIG. 3 is a plan view illustrating an example of a planar layout of the memory cell array included in the memory device according to the first embodiment. FIG. 3 illustrates four blocks BLK0 to BLK3 of the blocks BLK included in the memory cell array 10.

The memory cell array 10 includes a stacked wiring structure. The stacked wiring structure is a structure in which wiring layers (the word lines WL0 to WL14 and the select gate lines SGD and SGS) are stacked.

Hereinafter, a plane substantially parallel to the stacked plane of the wiring layer is referred to as an XY plane. Directions orthogonal to each other on the XY plane are defined as an X direction and a Y direction. A direction substantially perpendicular to the XY plane and extending from the select gate line SGS to the select gate line SGD is defined as a Z1 direction. A direction substantially perpendicular to the XY plane and extending from the select gate line SGD to the select gate line SGS is defined as a Z2 direction. In a case where the Z1 direction and the Z2 direction are not distinguished, the direction is referred to as a Z direction.

As illustrated in FIG. 3, the stacked wiring structure includes memory regions MRa and MRb arranged in the X direction and a hookup region HR. The memory regions MRa and MRb are regions in which the memory cell transistor MT is provided. The hookup region HR is a region provided with a contact that electrically connects each wiring layer and the row decoder module 15. The hookup region HR is located, for example, between the memory region MRa and the memory region MRb.

Each of the blocks BLK includes a portion extending in the X direction so as to cross the memory region MRa, the hookup region HR, and the memory region MRb in the stacked wiring structure. The blocks BLK are aligned in the Y direction. The memory cell array 10 includes, for example, a plurality of members SLT and a plurality of members SHE.

Although not illustrated in FIG. 3, for example, each member SLT has a structure in which a plate-shaped conductive member LI is embedded in a plate-shaped insulating member SP. Each member SLT extends in the X direction so as to cross the memory region MRa, the hookup region HR, and the memory region MRb. The members SLT are aligned in the Y direction. Each member SLT divides the adjacent wiring layers via the member SLT. In the memory cell array 10, each of the regions divided by the member SLT corresponds to one block BLK.

Each member SHE is, for example, a plate-like insulator. The members SHE include a plurality of members SHE aligned in the Y direction in the memory region MRa and a plurality of members SHE aligned in the Y direction in the memory region MRb. Each member SHE disposed in the memory region MRa extends in the X direction so as to cross the memory region MRa. Each member SHE disposed in the memory region MRb extends in the X direction so as to cross the memory region MRb.

In the example of FIG. 3, in each of the memory regions MRa and MRb, three members SHE are arranged between two members SLT adjacent in the Y direction. Each member SHE has, for example, a structure in which an insulator is embedded. Each member SHE divides the select gate lines SGD adjacent to each other via the member SHE in the wiring layers. In the memory cell array 10, each of regions divided by a pair of adjacent members SLT and SHE or a pair of adjacent two members SHE corresponds to one string unit SU.

The planar layout of the memory cell array 10 may be a different layout. For example, the number of members SHE disposed between two adjacent members SLT can be designed to be any number. The number of string units SU included in each block BLK can be changed based on the number of members SHE arranged between two adjacent members SLT.

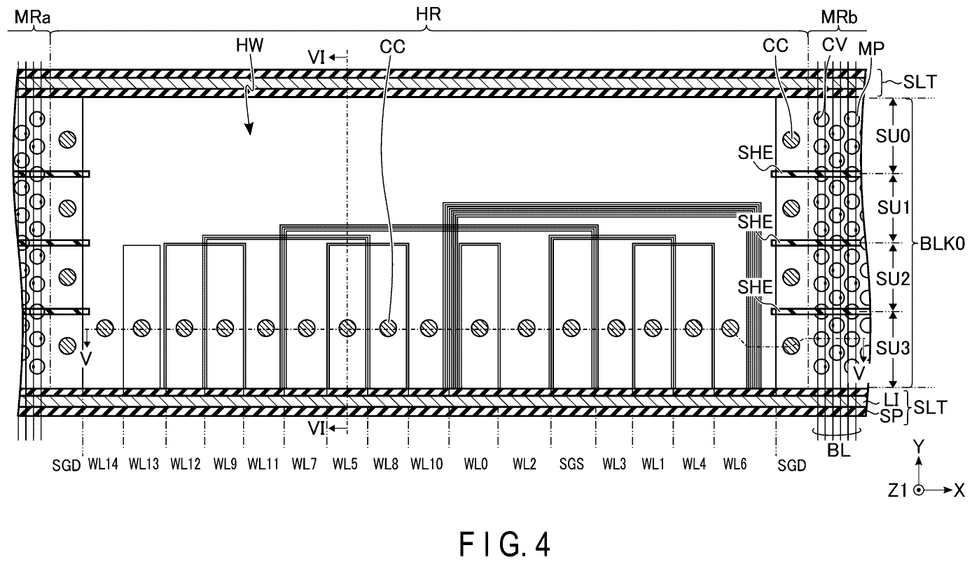

FIG. 4 is a plan view illustrating an example of a planar layout in the region IV of FIG. 3 in the memory cell array included in the memory device according to the first embodiment. In FIG. 4, a hookup region HR of the block BLK0 and boundary portions between the hookup region HR and the memory regions MRa and MRb are illustrated.

First, the planar layout of the memory cell array 10 in the memory regions MRa and MRb will be described.

As illustrated in FIG. 4, the memory cell array 10 includes a plurality of memory pillars MP, a plurality of contacts CV, and the bit lines BL in each of the memory regions MRa and MRb.

Each memory pillar MP functions as one NAND string NS. The memory pillars MP are arranged in 19 rows in a staggered manner, for example, in a region between two adjacent members SLT. For example, one member SHE is arranged to overlap each of the memory pillars MP of the fifth column, the memory pillars MP of the 10th column, and the memory pillars MP of the 15th column in a case of counting from the upper side in the drawing.

The bit lines BL are arranged in the X direction. Each bit line BL is arranged so as to overlap at least one memory pillar MP in each string unit SU. In the example of FIG. 4, two bit lines BL are arranged to overlap one memory pillar MP. The memory pillar MP is electrically connected to a bit line BL of the bit lines BL arranged in an overlapping manner via the contact CV. On the other hand, the contact CV between the memory pillar MP arranged to overlap with the member SHE (that is, the memory pillar MP contact with two different select gate lines SGD) and the bit line BL can be omitted.

Note that the planar layout in the memory region MR may be a different layout. For example, the number and arrangement of the memory pillars MP and the members SHE arranged between two adjacent members SLT can be appropriately changed. The number of bit lines BL overlapping each memory pillar MP can be designed to an any number.

Next, the planar layout of the memory cell array 10 in the hookup region HR will be described.

In the hookup region HR, each wiring layer constituting the stacked wiring structure has a terrace portion. The terrace portion is a portion formed in a staircase shape in the stacked wiring structure. The terrace portion may be a portion where each wiring layer does not overlap the upper wiring layer in the Z1 direction (that is, select gate line SGD side). The terrace portion may include a portion thicker than other portions of each wiring layer. The adjacent terrace portions are aligned in the X direction, for example.

In the example of FIG. 4, the terrace portions of the wiring layers except the select gate line SGD are arranged in the X direction in the order of the word lines WL14, WL13, (WL14), WL12, WL9, WL11, WL7, WL5, WL8, WL10, WL0, and WL2, the select gate line SGS, and the word lines WL3, WL1, WL4, WL6, and (WL14). Here, the terrace portions with parentheses are terrace portions where contacts CC are not provided. The terrace portion of each wiring layer forms a step with the terrace portion of another adjacent wiring layer. Hereinafter, a set of a wiring layer and an interlayer insulating film stacked on a portion of the wiring layer which is not thickened will be described as a unit of the height of the step (one step) in the Z direction.

The step in the X direction in the example of FIG. 4 will be specifically described. The word line WL14 forms steps with one-step height, two-steps height, three-steps height, four-steps height, and eight-steps height with the terrace portions of the word lines WL13, WL12, WL11, WL10, and WL6, respectively. The terrace portion of each of the word lines WL12 and WL9 forms a step with three-steps height. The terrace portion of each of the word lines WL9 and WL11 forms a step with two-steps height. The terrace portion of each of the word lines WL11 and WL7 forms a step with four-steps height. The terrace portion of each of the word lines WL7 and WL5 forms a step with two-steps height. The terrace portion of each of the word lines WL5 and WL8 forms a step with three-steps height. The terrace portion of each of the word lines WL8 and WL10 forms a step with two-steps height. The terrace portion of each of the word lines WL10 and WL0 forms a step with ten-steps height. The terrace portion of each of the word lines WL0 and WL2 forms a step with two-steps height. The terrace portion of each of the word line WL2 and the select gate line SGS forms a step with three-steps height. The terrace portion of each of the select gate line SGS and the word line WL3 forms a step with four-steps height. The terrace portion of each of the word lines WL3 and WL1 forms a step with two-steps height. The terrace portion of each of the word lines WL1 and WL4 forms a step with three-steps height. The terrace portion of each of the word lines WL4 and WL6 forms a step with two-steps height.

As described above, the minimum height of the steps formed between the terrace portions of the select gate line SGS and the word lines WL0 to WL12 and other adjacent terrace portions is two or more-steps height. In other words, between one of the terrace portions of the select gate line SGS and the word lines WL0 to WL12 and each of a plurality of other terrace portions adjacent to the one of the terrace portions as viewed in the Z direction, there is at least one wiring layer other than the two wiring layers having the two adjacent terrace portions. Like the terrace portions of the word lines WL0 and WL2, the select gate line SGS, and the word lines WL3 and WL1, there are portions where the positions in the Z direction of the five terrace portions arranged adjacent to each other in this order in the X direction are zigzag. In other words, the first and third terrace portions among the five terrace portions arranged in the X direction are located on the same side in the Z direction with respect to the second terrace portion. The third and fifth terrace portions are located on the same side in the Z direction with respect to the fourth terrace portion.

In addition, the terrace portion of the word line WL13 forms a step with one-step height with the terrace portion of the word line WL14. There is a terrace portion of the word line WL14 between the terrace portion of each of the select gate line SGS and the word lines WL0 to WL12 and the terrace portion of the word line WL13. In other words, the terrace portion of the word line WL13 is not adjacent to the terrace portion of each of the select gate line SGS and the word lines WL0 to WL12.

In the first embodiment, the only terrace portion not adjacent to any of the terrace portions of the select gate line SGS and the word lines WL0 to WL12 is the terrace portion of the word line WL13. In this case, each of the terrace portions of the four consecutive wiring layers (that is, the word lines WL13 to WL10) counted from the uppermost word line WL14 is directly adjacent to the terrace portion of the word line WL14.

The wiring layer of the memory region MRa and the wiring layer of the memory region MRb are continuous via a portion of the hookup region HR excluding the terrace portion except for the select gate line SGD. Hereinafter, in the hookup region HR, this portion connecting the wiring layer on the memory region WRa side and the wiring layer on the memory region WRb side in the X direction is also referred to as a highway portion HW. In other words, the highway portion HW is a portion that electrically connects the wiring layer excluding the select gate line SGD between the memory region MRa and the memory region MRb. The select gate line SGD is divided into a portion of the memory region MRa and a portion of the memory region MRb by the hookup region HR.

The memory cell array 10 includes the contacts CC in the hookup region HR. The contact CC is a conductor used for connection between the row decoder module 15 and each wiring layer. The contacts CC associated with the block BLK are connected to the terrace portions of the select gate lines SGS and SGD and the word lines WL0 to WL14 provided in the hookup region HR, respectively. Note that different contacts CC are provided for the select gate line SGD on the memory region MRa side and the select gate line SGD on the memory region MRb side. The select gate line SGD on the memory region MRa side and the select gate line SGD on the memory region MRb side associated with the same string unit SU are electrically connected via, for example, each contact CC and a wiring layer (not illustrated) provided on the Z1 direction side of the memory cell array 10.

### 1.1.3.3 Cross-Sectional Structure

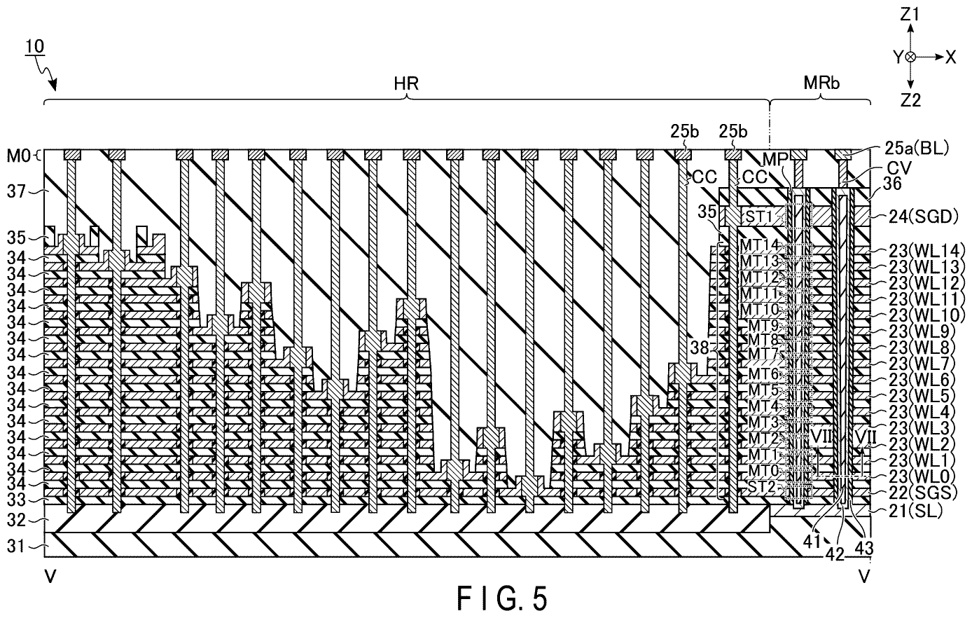

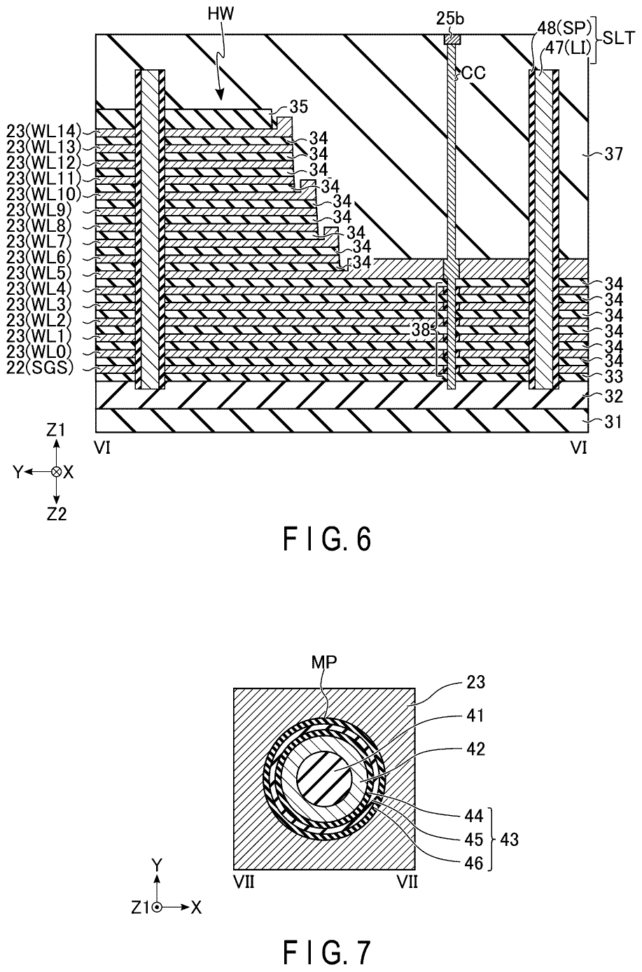

FIG. 5 is a cross-sectional view taken along a line V-V of FIG. 4, illustrating an example of a cross-sectional structure of the memory cell array included in the memory device according to the first embodiment. FIG. 6 is a cross-sectional view taken along a line VI-VI of FIG. 4, illustrating an example of the cross-sectional structure of the memory cell array included in the memory device according to the first embodiment. FIG. 5 illustrates an XZ cross-sectional structure of a portion including the terrace portion of each wiring layer in the memory region MRb and the hookup region HR. In FIG. 6, the YZ cross-sectional structure of a portion including the terrace portion of the word line WL5 in the hookup region HR is illustrated.

As illustrated in FIGS. 5 and 6, the memory cell array 10 includes, for example, a semiconductor layer 21, wiring layers 22, 23, and 24, conductive layers 25 (25a and 25b), insulating layers 31, 32, 33, 34, 35, 36, and 37, insulating films 38 and 48, and a conductor film 47. The insulating layers 31, 33, 34, 35, 36, and 37 and the insulating films 38 and 48 include, for example, silicon oxide. The insulating layer 32 includes, for example, amorphous silicon. In FIGS. 5 and 6, the Z1 direction corresponds to the upper side of the drawing.

The insulating layer 32 and the semiconductor layer 21 are provided on the insulating layer 31. The insulating layer 32 is formed in, for example, a plate shape extending in the XY plane in the hookup region HR. The semiconductor layer 21 is formed in, for example, a plate shape extending in the XY plane in the memory region MRb and the memory region MRa (not illustrated), and is not provided in the hookup region HR. In other words, the semiconductor layer 21 does not overlap each terrace portion as viewed in the Z direction. The film thickness of the semiconductor layer 21 is thinner than the film thickness of the insulating layer 32. The upper surfaces of the semiconductor layer 21 and the insulating layer 32 in the Z1 direction are aligned. The semiconductor layer 21 contains, for example, polysilicon and is used as the source line SL.

The insulating layer 33 is provided on the semiconductor layer 21 and the insulating layer 32. The wiring layer 22 is provided on the insulating layer 33. The wiring layer 22 is formed in, for example, a plate shape extending in the XY plane. The wiring layer 22 contains, for example, tungsten or molybdenum, and is used as the select gate line SGS.

The insulating layers 34 and wiring layers 23 are alternately provided on the wiring layer 22. The wiring layers 23 are formed in, for example, a plate shape extending in the XY plane. The wiring layers 23 contain, for example, tungsten or molybdenum, and are used as the word lines WL0 to WL14, respectively, in order from the semiconductor layer 21 side.

The wiring layer on the lower side (lower wiring layer) in the Z1 direction of the two terrace portions adjacent to each other as viewed in the Z direction has a portion (normal portion) not thickened at the boundary with the terrace portion of the wiring layer on the upper side (upper wiring layer) in the Z1 direction. Then, the terrace portion of the lower wiring layer forms a step with the terrace portion of the upper wiring layer via the normal portion. As a result, the terrace portion of the lower wiring layer is electrically insulated from the wiring layer present on the side surface of the step.

The terrace portion of the upper wiring layer excluding the uppermost wiring layer 23 (corresponding to the word line WL14) of the two adjacent terrace portions forms a step with the terrace portion of the lower wiring layer without interposing the normal portion.

The uppermost wiring layer 23 has a normal portion at the boundary with the terrace portion of the lower wiring layer (the wiring layer 23 corresponding to the word line WL13) forming a step with one-step height. The terrace portion of the uppermost wiring layer 23 forms a step with the terrace portion of the lower wiring layer via the normal portion.

Then, the insulating layer 35 is provided on the normal portion of the uppermost wiring layer 23 so as not to be in contact with the thick film portion of the uppermost wiring layer 23. The insulating layer 35 is at least thicker than the film thickness (that is, a thickness corresponding to a step with one-step height) of a set of an insulating layer 34 and a wiring layer 23. Therefore, the height of the step formed between the terrace portion of the uppermost wiring layer 23 and the terrace portion of the lower wiring layer is substantially equal to or more than two-steps height due to the insulating layer 35.

The wiring layer 24 is provided on the insulating layer 35. The wiring layer 24 is formed in, for example, a plate shape extending in the XY plane. The entire wiring layer 24 has a film thickness equal to or more than the terrace portion of each of the wiring layer 22 and the wiring layers 23. The wiring layer 24 contains, for example, tungsten or molybdenum, and is used as the select gate line SGD. The insulating layer 36 is provided on the wiring layer 24.

The member SLT includes the conductor film 47 and the insulating film 48. The conductor film 47 is a plate-like conductor extending on the XZ plane. The conductor film 47 penetrates the wiring layers 22 to 24 and the insulating layers 33 to 36 and reaches the insulating layer 32. The conductor film 47 is used as the conductive member LI. The insulating film 48 is an insulator covering a side surface of the conductor film 47. The insulating film 48 penetrates the wiring layers 22 to 24 and the insulating layers 33 to 36 and reaches the semiconductor layer 21 or the insulating layer 32. The insulating film 48 electrically insulates the conductor film 47 from each of the wiring layers 22 to 24, and is used as an insulating member SP. Note that the structure of the member SLT is not limited thereto, and may be, for example, a structure in which the conductive member LI is omitted and an insulator forming the insulating member SP is embedded.

In the memory region MRb, each of the memory pillars MP extends in the Z direction and penetrates the wiring layers 22 to 24 and the insulating layers 33 to 36. Note that, although not illustrated in FIG. 5, a plurality of memory pillars MP is provided in the memory region MRa in a similar manner.

Each of the memory pillars MP includes, for example, a core film 41, a semiconductor film 42, and a stacked film 43. The core film 41 is an insulator extending in the Z direction. The semiconductor film 42 covers the core film 41. The lower portion of the semiconductor film 42 is in contact with the semiconductor layer 21. The stacked film 43 covers the side surface of the semiconductor film 42.

FIG. 7 is a cross-sectional view taken along a line VII-VII of FIG. 5, illustrating an example of a cross-sectional structure of the memory pillar included in the memory device according to the first embodiment. FIG. 7 illustrates a cross section, parallel to the XY plane, including the memory pillar MP and the wiring layer 23. As illustrated in FIG. 7, the stacked film 43 includes, for example, a tunnel insulating film 44, a charge storage film 45, and a block insulating film 46.

The core film 41 is provided, for example, in a central portion of the memory pillar MP. The semiconductor film 42 surrounds the side surface of the core film 41. The tunnel insulating film 44 surrounds the side surface of the semiconductor film 42. The charge storage film 45 surrounds the side surface of the tunnel insulating film 44. The block insulating film 46 surrounds the side surface of the charge storage film 45. The wiring layer 23 surrounds the side surface of the block insulating film 46. The semiconductor film 42 is used as a channel (current path) of the memory cell transistors MT0 to MT14 and the select transistors ST1 and ST2. Each of the tunnel insulating film 44 and the block insulating film 46 contains, for example, silicon oxide. The charge storage film 45 includes, for example, silicon nitride.

With the above configuration, each of the memory pillars MP functions as a NAND string NS. In other words, a portion where the memory pillar MP intersects the wiring layer 22 functions as the select transistor ST2. A portion where the memory pillar MP intersects the wiring layer 23 functions as the memory cell transistor MT. A portion where the memory pillar MP intersects the wiring layer 24 functions as the select transistor ST1.

The contact CV is provided on the upper surface of the semiconductor film 42 in the Z1 direction in the memory pillar MP. On the upper surface of the contact CV in the Z1 direction, the conductive layer 25a is provided. The conductive layer 25a is formed in, for example, a line shape extending in the Y direction. The conductive layer 25a contains, for example, copper and is used as the bit line BL.

In the hookup region HR, each of the contacts CC extends in the Z direction, penetrates the wiring layers 22 to 24 and the insulating layers 33 to 36, and reaches the insulating layer 32. Each of the contacts CC is in contact with the thick film portion of the terrace portion of the corresponding wiring layer in the wiring layers 22 to 24. The insulating film 38 is provided between each of the contacts CC and each of the wiring layers excluding the corresponding wiring layer in the wiring layers 22 to 24. Each of the contacts CC is electrically insulated, by the insulating film 38, from each of the wiring layers except for the corresponding wiring layer of the wiring layers 22 to 24.

The conductive layer 25b is provided on the upper surface of the contact CC in the Z1 direction. The conductive layer 25b contains copper for example and is provided in the same layer as the conductive layer 25a. Hereinafter, the layer in which the conductive layers 25a and 25b are provided is referred to as a layer M0.

The insulating layer 37 is provided so as to cover the stacked wiring structure, the contacts CC and CV, and the conductive layers 25a and 25b as described above.

### 1.1.4 Structure of Memory Device

Next, a structure of the memory device according to the first embodiment will be described.

### 1.1.4.1 Bonding Structure

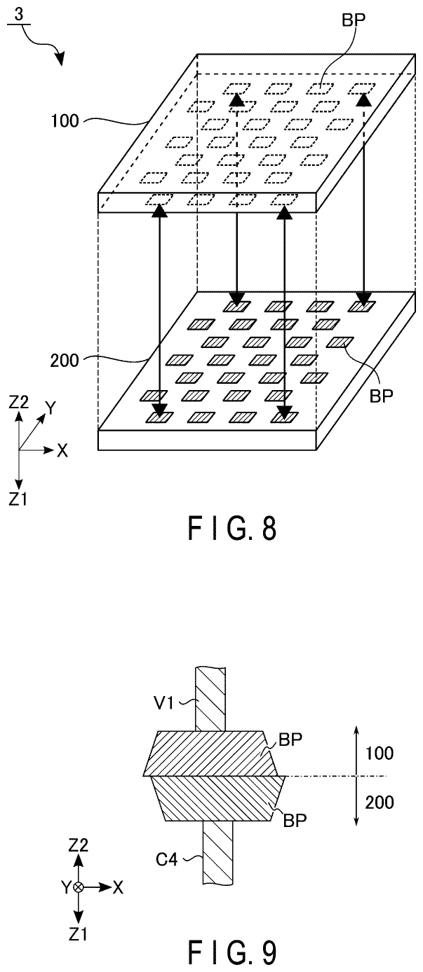

FIG. 8 is a perspective view illustrating an outline of a bonding structure of the memory device according to the first embodiment. As illustrated in FIG. 8, the memory device 3 includes a memory chip 100 and a circuit chip 200. The memory chip 100 includes a structure corresponding to the memory cell array 10. The circuit chip 200 includes, for example, a structure corresponding to the command register 11, the address register 12, the sequencer 13, the driver module 14, the row decoder module 15, and the sense amplifier module 16.

In addition, each of the memory chip 100 and the circuit chip 200 includes a plurality of bonding pads BP. The memory device 3 is formed by bonding the memory chip 100 and the circuit chip 200 via the bonding pads BP.

### 1.1.4.2 Bonding Pads

FIG. 9 is a cross-sectional view illustrating an example of a cross-sectional structure of the bonding pads included in the memory device according to the first embodiment. In the example of FIG. 9, the bonding pads BP and the contacts V1 and C4 of each of the memory chip 100 and the circuit chip 200 on the bonding surfaces are illustrated.

As illustrated in FIG. 9, in the bonding step, the bonding pads BP of the memory chip 100 are connected to the bonding pads BP of the circuit chip 200. In the example of FIG. 9, the areas of the respective bonding pads BP of the memory chip 100 and the circuit chip 200 on the bonding surfaces are substantially equal. In such a case, if copper is used for the bonding pads BP, the copper of the bonding pads BP of the memory chip 100 and the copper of the bonding pads BP of the circuit chip 200 are integrated, and it may be difficult to confirm the boundary between the copper. However, bonding can be confirmed by shape distortion due to positional deviation of bonding between the bonding pads BP and positional deviation of a copper barrier metal (occurrence of a discontinuous portion on a side surface).

In a case where the bonding pads BP are formed by a damascene method, each side surface has a tapered shape. Therefore, in the portion where the bonding pads BP are bonded to each other, the side wall does not have a linear shape in the cross section along the Z direction, and the cross section has a non-rectangular shape.

In addition, in a case where the bonding pads BP are bonded to each other, a bottom surface, a side surface, and an upper surface of copper forming the bonding pads BP are covered with the barrier metal. On the other hand, in a general wiring layer using copper, an insulating layer (silicon nitride, silicon carbonitride, or the like) having a function of preventing oxidation of copper is provided on the upper surface of copper, and no barrier metal is provided. Therefore, it is possible to distinguish from a general wiring layer even if no positional deviation of bonding occurs.

### 1.1.4.3 Cross-Sectional Structure

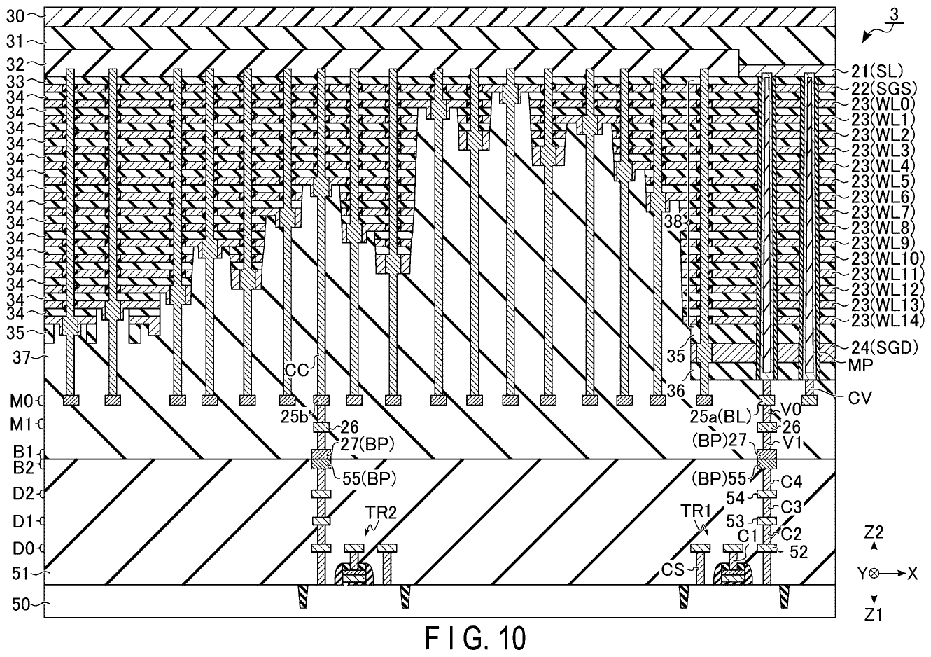

FIG. 10 is a cross-sectional view illustrating an example of a cross-sectional structure of the memory device according to the first embodiment. In FIG. 10, the Z2 direction corresponds to the upper side of the drawing.

As illustrated in FIG. 10, the memory device 3 further includes conductive layers 26 and 27, a protective layer 30, and contacts V0 and V1 in the memory chip 100. The memory device 3 includes a substrate 50, an insulating layer 51, conductive layers 52, 53, 54, and 55, transistors TR1 and TR2, and contacts CS, C1, C2, C3, and C4 in the circuit chip 200.

First, the memory chip 100 will be described.

The protective layer 30 is provided on the upper surface of the insulating layer 31 in the Z2 direction. The protective layer 30 is a layer corresponding to the surface of the memory device 3, and includes, for example, a resin material such as polyimide. In a region not illustrated, a part of the protective layer 30 is removed. Then, a pad electrode responsible for electrical connection with the outside is provided in the portion from which the protective layer 30 is removed.

The contact V0 is provided on the upper surface of each of the conductive layers 25a and 25b in the Z1 direction. On the upper surface of the contact V0 in the Z1 direction, the conductive layer 26 is provided.

On the upper surface of the conductive layer 26 in the Z1 direction, the contact V1 is provided. On the upper surface of the contact V1 in the Z1 direction, the conductive layer 27 is provided. The conductive layer 27 functions as a bonding pad BP on the bonding surface of the memory chip 100 with the circuit chip 200. The conductive layers 26 and 27 and the contacts V0 and V1 are covered with the insulating layer 37. Hereinafter, the layers on which the conductive layers 26 and 27 are provided are referred to as a layer M1 and a bonding layer B1, respectively.

Next, the circuit chip 200 will be described.

The substrate 50 is a silicon substrate. On the substrate 50, the transistors TR1 and TR2 are provided. On the upper surface in the Z2 direction of the substrate 50 provided with the transistors TR1 and TR2, the insulating layer 51 is provided.

The transistors TR1 and TR2 are structures constituting various circuits provided in the circuit chip 200. In the example of FIG. 10, the transistor TR1 corresponds to a circuit (for example, a transistor in the sense amplifier module 16) connected to the bit line BL. The transistor TR2 corresponds to a circuit (for example, a transistor in the row decoder module 15) connected to the word line WL.

On the upper surface of the gate electrode of each of the transistors TR1 and TR2 in the Z2 direction, the contact C1 is provided. The contact CS is provided on an upper surface in the Z2 direction of a region functioning as a source or a drain of each of the transistors TR1 and TR2 in the substrate 50. On the upper surface of each of the contacts CS and C1 in the Z2 direction, the conductive layer 52 is provided.

On the upper surface of the conductive layer 52 in the Z2 direction, the contact C2 is provided. On the upper surface of the contact C2 in the Z2 direction, the conductive layer 53 is provided. A contact C3 is provided on the upper surface of the conductive layer 53 in the Z2 direction. On the upper surface of the contact C3 in the Z2 direction, the conductive layer 54 is provided. On the upper surface of the conductive layer 54 in the Z2 direction, the contact C4 is provided. On the upper surface of the contact C4 in the Z2 direction, the conductive layer 55 is provided. The conductive layer 55 is in contact with the corresponding conductive layer 27 and functions as the bonding pad BP on the bonding surface of the circuit chip 200 to the memory chip 100. The conductive layers 52, 53, 54, and 55 and the contacts CS, C1, C2, C3, and C4 are covered by the insulating layer 51. Hereinafter, the layers on which the conductive layers 52, 53, 54, and 55 are provided are referred to as layers D0, D1, and D2, and a bonding layer B2, respectively.

### 1.2 Manufacturing Method

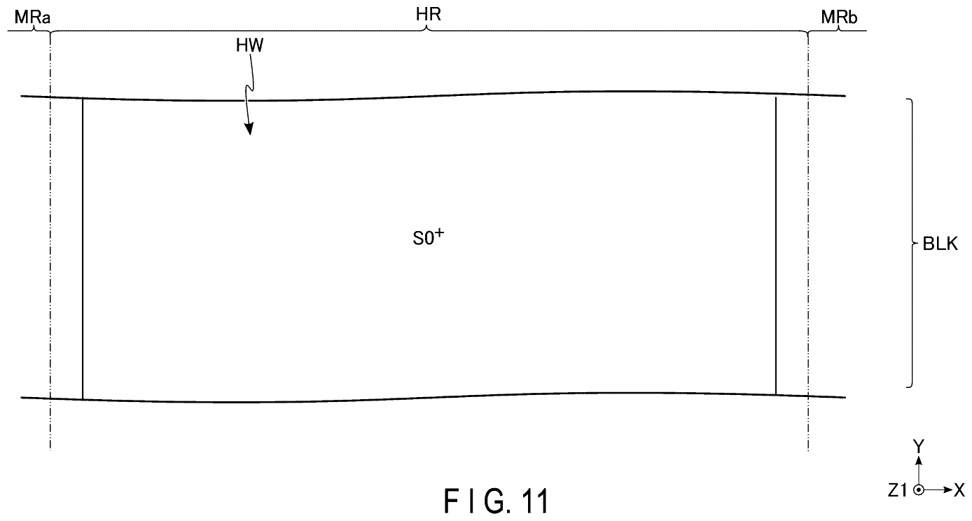

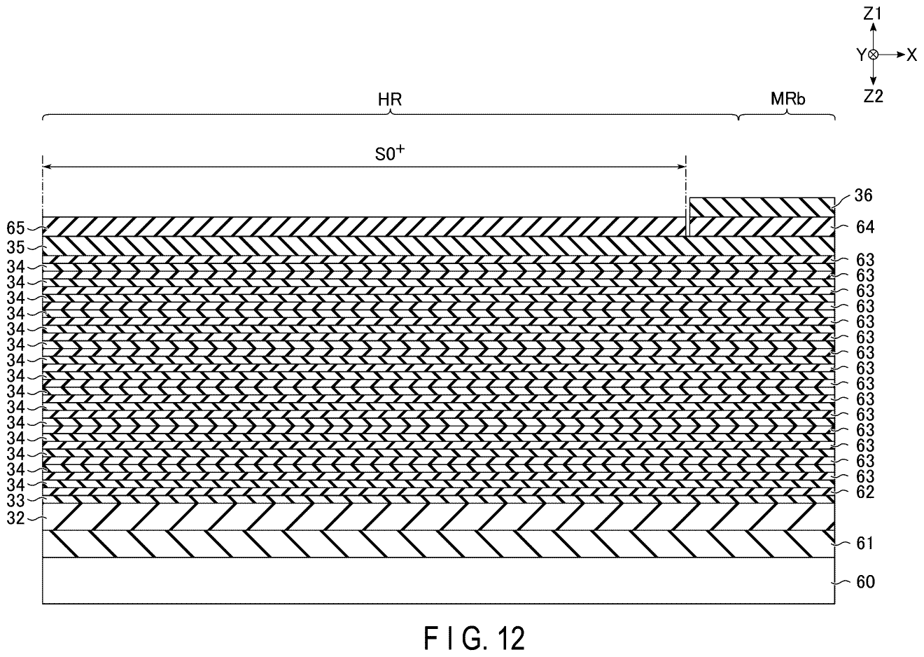

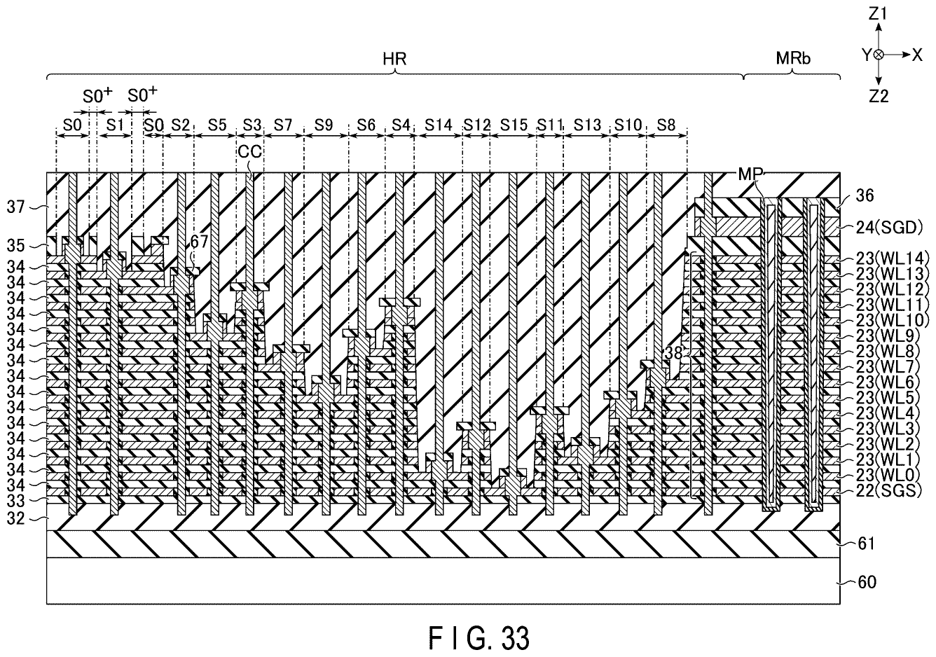

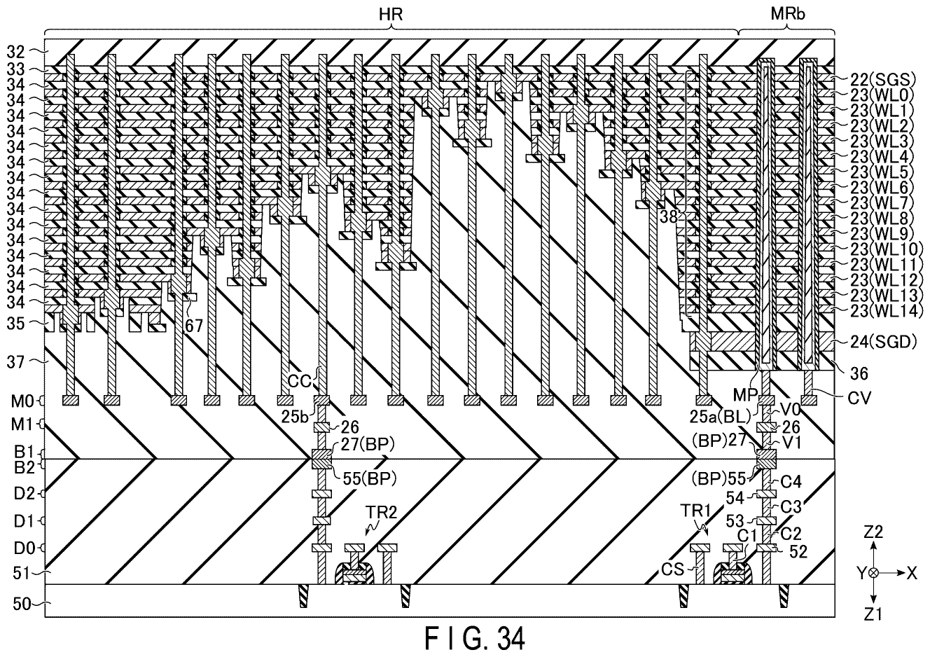

FIGS. 11 to 34 are diagrams illustrating examples of a structure in a process of manufacturing the memory device according to the first embodiment. Among these drawings, FIGS. 11, 13, 15, 17, 19, 21, and 23 are planar layouts in the process of manufacturing the memory cell array 10 in the memory chip 100, and correspond to FIG. 4. FIGS. 12, 14, 16, 18, 20, 22, 24, and 25 to 32 are cross-sectional views in the process of manufacturing the memory cell array 10 in the memory chip 100, and correspond to FIG. 5. FIGS. 33 and 34 are cross-sectional views in the process of manufacturing the memory device 3 in the memory chip 100 and the circuit chip 200 after bonding, and correspond to FIG. 10.

The memory chip 100 and the circuit chip 200 are separately manufactured. Hereinafter, a method of manufacturing the memory chip 100 will be focused.

First, the insulating layer 61 is provided on the upper surface of the substrate 60 in the Z1 direction. On the upper surface of the insulating layer 61 in the Z1 direction, the insulating layer 32 is provided. The substrate 60 is used to manufacture the memory chip 100, and includes, for example, silicon. The insulating layer 61 includes, for example, silicon oxide.

Subsequently, on the insulating layer 61, a stacked structure corresponding to the stacked wiring structure is provided. Specifically, the insulating layer 33 and a sacrificial layer 62 are sequentially provided on the upper surface of the insulating layer 32 in the Z1 direction. On the upper surface of the sacrificial layer 62 in the Z1 direction, the insulating layers 34 and the sacrificial layers 63 are alternately stacked. On the upper surface of the uppermost sacrificial layer 63 in the Z1 direction, the insulating layer 35 and the sacrificial layer 64 are sequentially provided. On the upper surface of the sacrificial layer 64 in the Z1 direction, the insulating layer 36 is provided. The sacrificial layers 62 to 64 includes, for example, silicon nitride.

Next, as illustrated in FIGS. 11 and 12, the sacrificial layer 64 and the insulating layer 36 in the region excluding the terrace portion of the select gate line SGD in the hookup region HR are removed by, for example, reactive ion etching (RIE). As a result, the insulating layer 35 is exposed in the region where the sacrificial layer 64 and the insulating layer 36 are removed. On the upper surface of the insulating layer 35 in the Z1 direction, a stop layer 65 is provided. The stop layer 65 contains, for example, silicon nitride.

Hereinafter, a region where the stop layer 65 and the insulating layer 35 in an unetched state (that is, a state in which the film is thicker than the insulating layers 33 and 34.) exist is indicated as a region S0⁺.

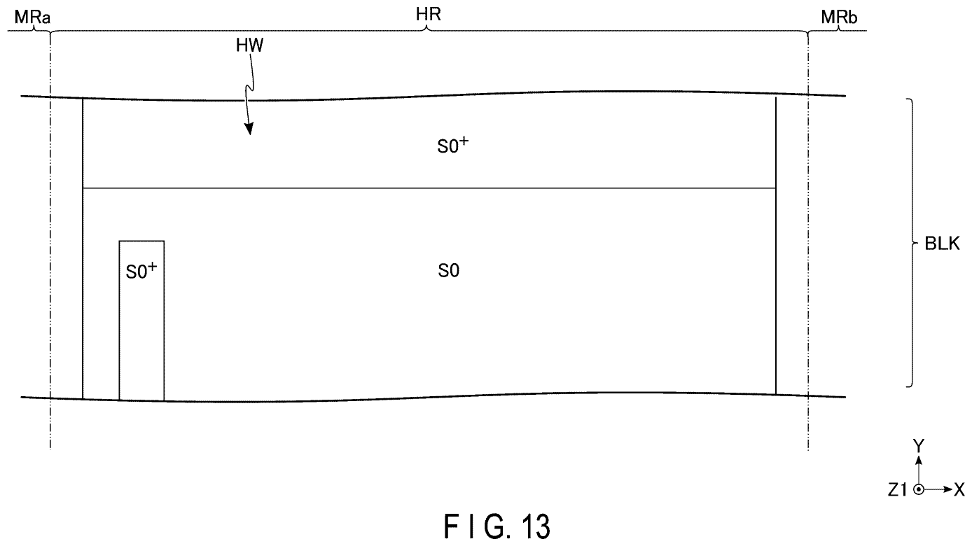

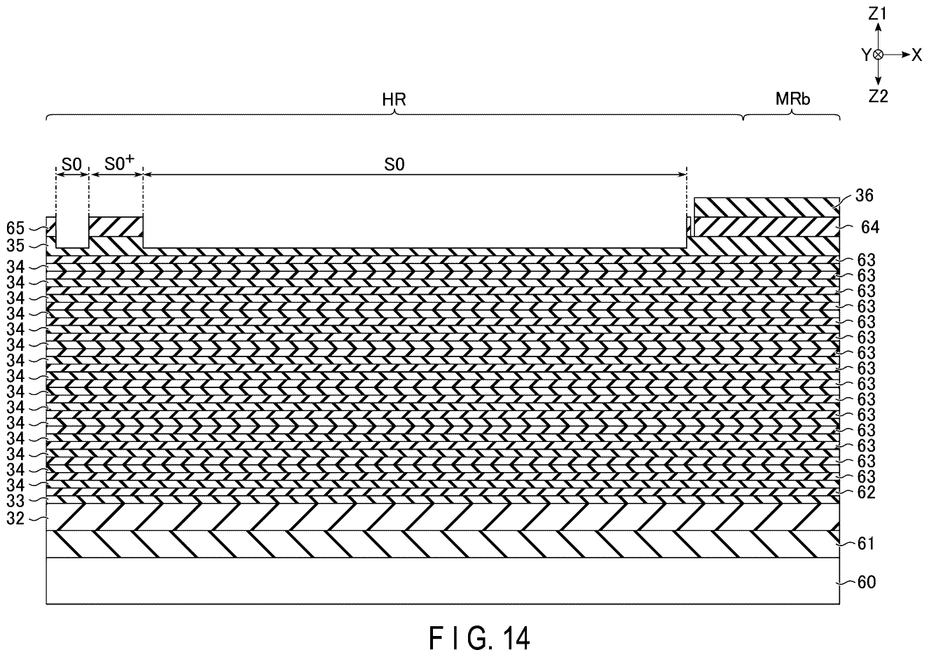

Next, as illustrated in FIGS. 13 and 14, in the region S0⁺, a region S0 excluding a region including the terrace portion of the word line WL13 and a region where the highway portion HW is to be formed is etched. As a result, the stop layer 65 in the region S0 and a part of the insulating layer 35 are removed. The film thickness of the insulating layer 35 in the region S0 is, for example, equivalent to the film thickness of the insulating layers 33 and 34.

Hereinafter, a region where the insulating layer 35 processed to have a film thickness equivalent to that of the insulating layers 33 and 34 is present is indicated as a region S0. In addition, a region where the stacked structure is etched to form a staircase structure is indicated as a region Sk according to the depth k. Here, the depth k is an integer that is equal to or greater than one, and corresponds to the number of steps processed (number of sets of the insulating layer 34 and the sacrificial layer 62 or 63 processed) counted from the region S0.

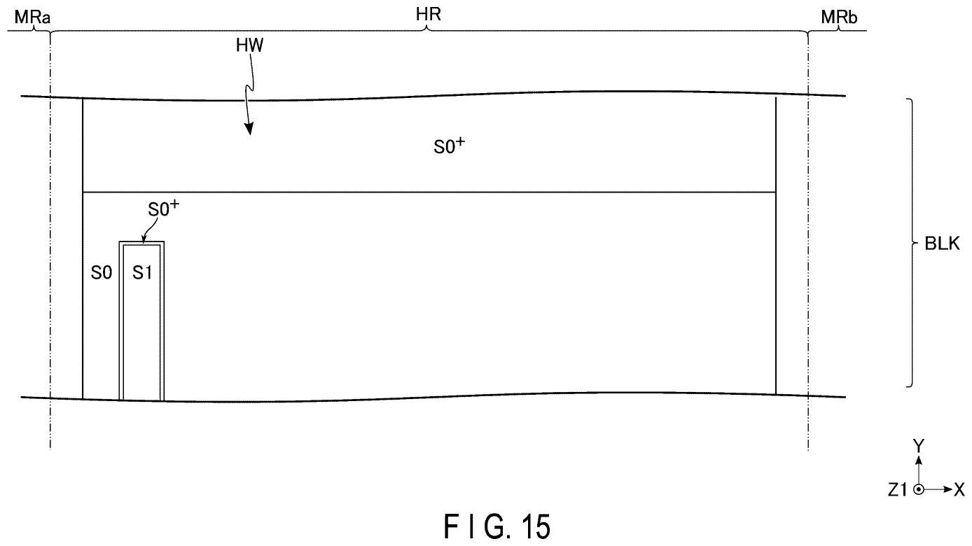

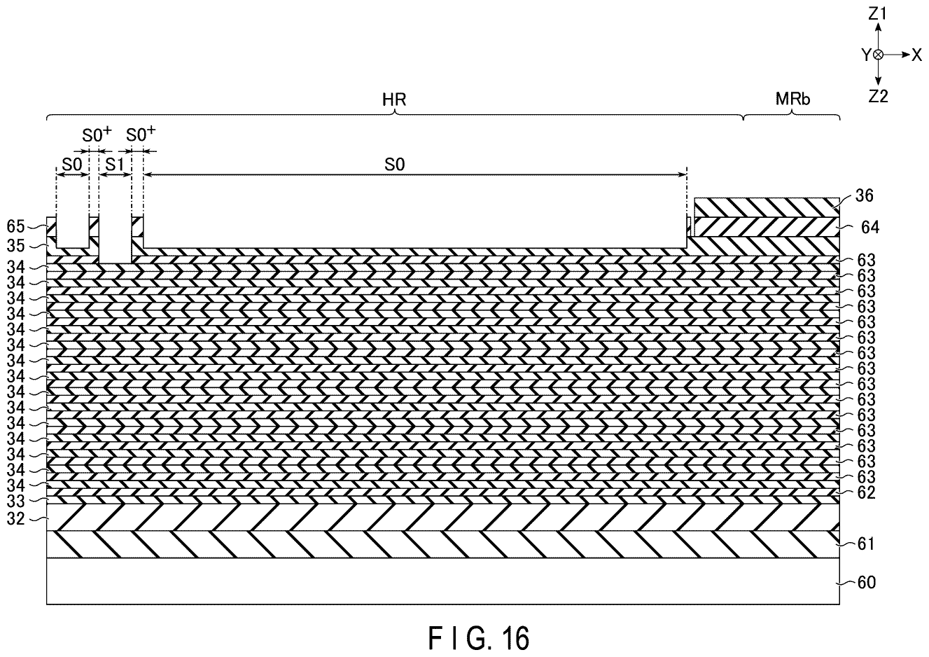

Next, as illustrated in FIGS. 15 and 16, a region including the terrace portion of the word line WL13 in the region S0⁺is etched. Specifically, the stop layer 65, the insulating layer 35, and the uppermost sacrificial layer 63 are removed in the region including the terrace portion of the word line WL13 in the region S0⁺. As a result, the region including the terrace portion of the word line WL13 forms a region S1, and is made lower in the Z2 direction by one-step height with respect to the region S0.

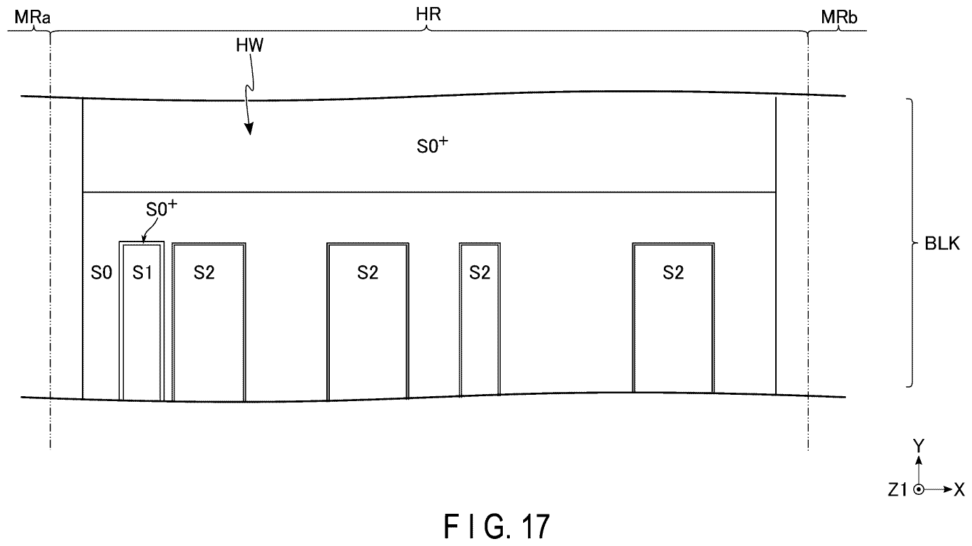

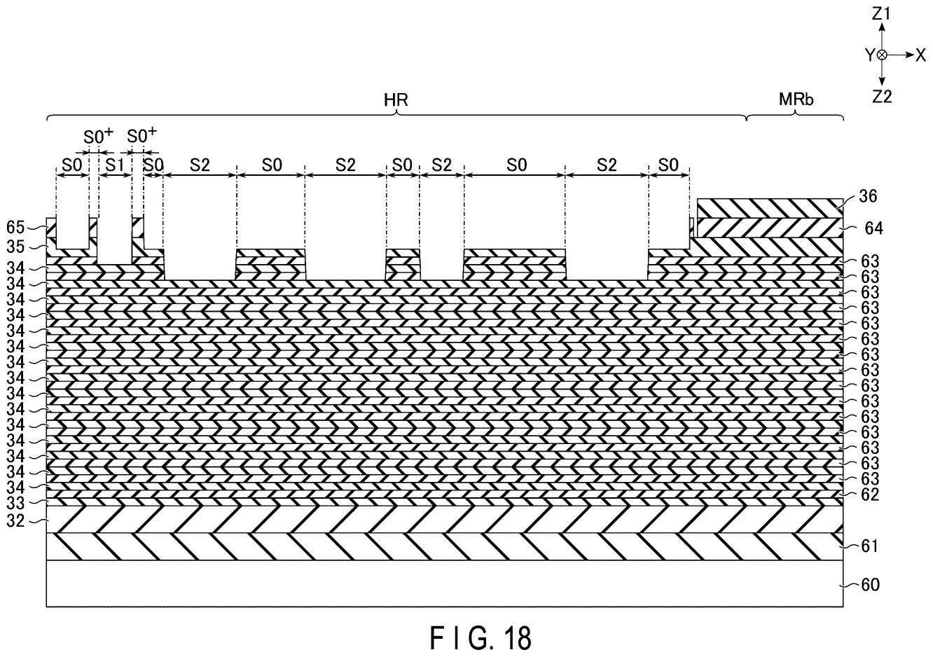

Next, as illustrated in FIGS. 17 and 18, a region including the terrace portions of the word lines WL12 and WL9, a region including the terrace portions of the word lines WL5 and WL8, a region including the terrace portion of the word line WL0, and a region including the terrace portions of the word lines WL1 and WL4 are etched. Specifically, the insulating layer 35, the uppermost sacrificial layer 63, and the insulating layer 34 and the sacrificial layer 63 for one-step height are removed in each of the region including the terrace portions of the word lines WL12 and WL9, the region including the terrace portions of the word lines WL5 and WL8, the region including the terrace portion of the word line WL0, and the region including the terrace portions of the word lines WL1 and WL4. As a result, each of the region including the terrace portions of the word lines WL12 and WL9, the region including the terrace portions of the word lines WL5 and WL8, the region including the terrace portion of the word line WL0, and the region including the terrace portions of the word lines WL1 and WL4 forms a region S2, and is made lower in the Z2 direction by two-steps height with respect to the region S0.

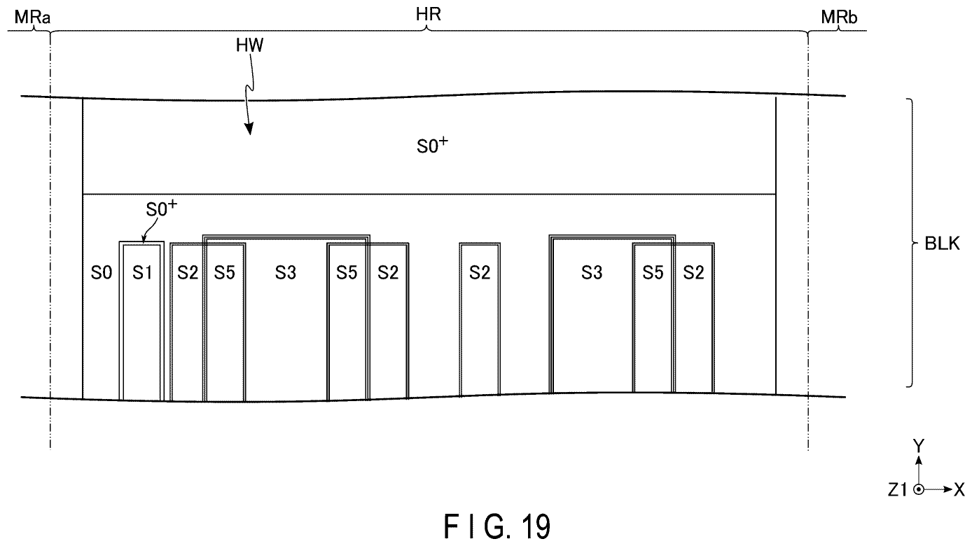

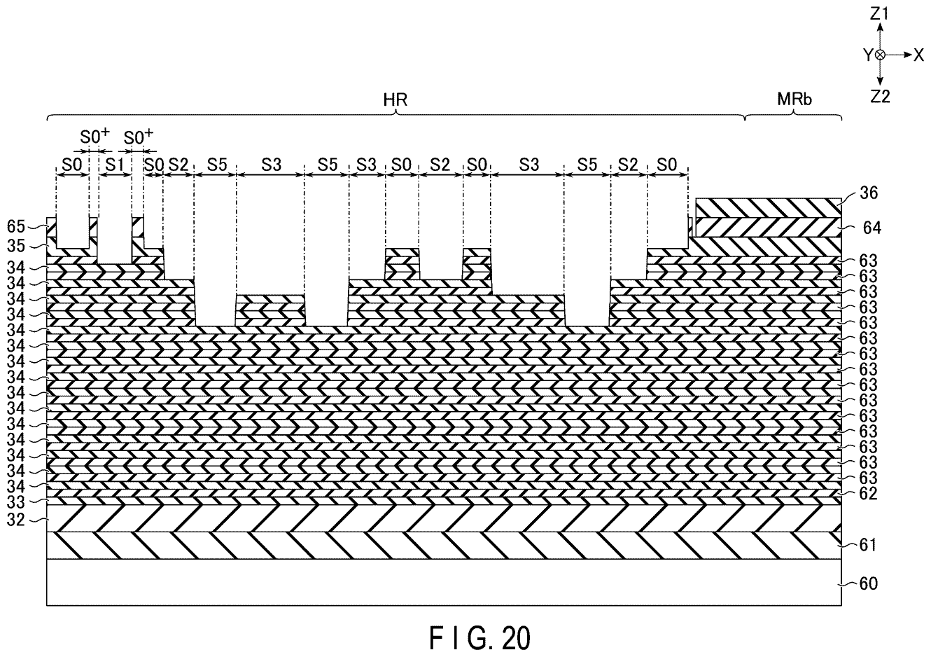

Next, as illustrated in FIGS. 19 and 20, a region including the terrace portions of the word lines WL9, WL11, WL7, and WL5 and a region including the terrace portions of the select gate lines SGS, the word lines WL3, and WL1 are etched. Specifically, in each of the region including the terrace portions of the word lines WL9, WL11, WL7, and WL5 and the region including the terrace portions of the select gate line SGS, the word lines WL3, and WL1, the insulating layer 34 and the sacrificial layer 63 for three-steps height (for three-steps height including the uppermost insulating layer 35 in a partial region) are removed. As a result, each of the region including the terrace portions of the word lines WL11 and WL7 and the region including the terrace portions of the select gate line SGS and the word line WL3 forms a region S3, and is made lower in the Z2 direction by three-steps height with respect to the region S0. In addition, each of the region including the terrace portion of the word line WL9, the region including the terrace portion of the word line WL5, and the region including the terrace portion of the word line WL1 forms a region S5, and is made lower in the Z2 direction by five-steps height with respect to the region S0.

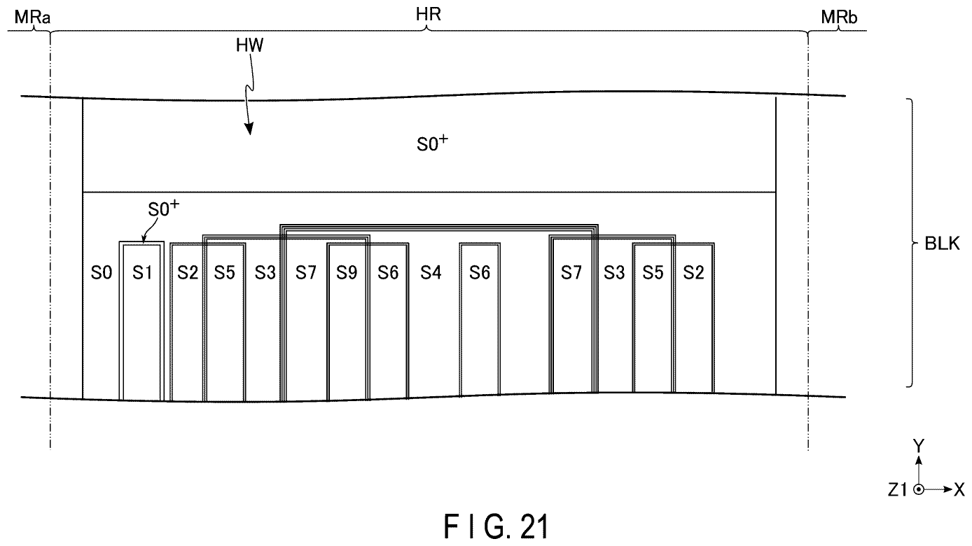

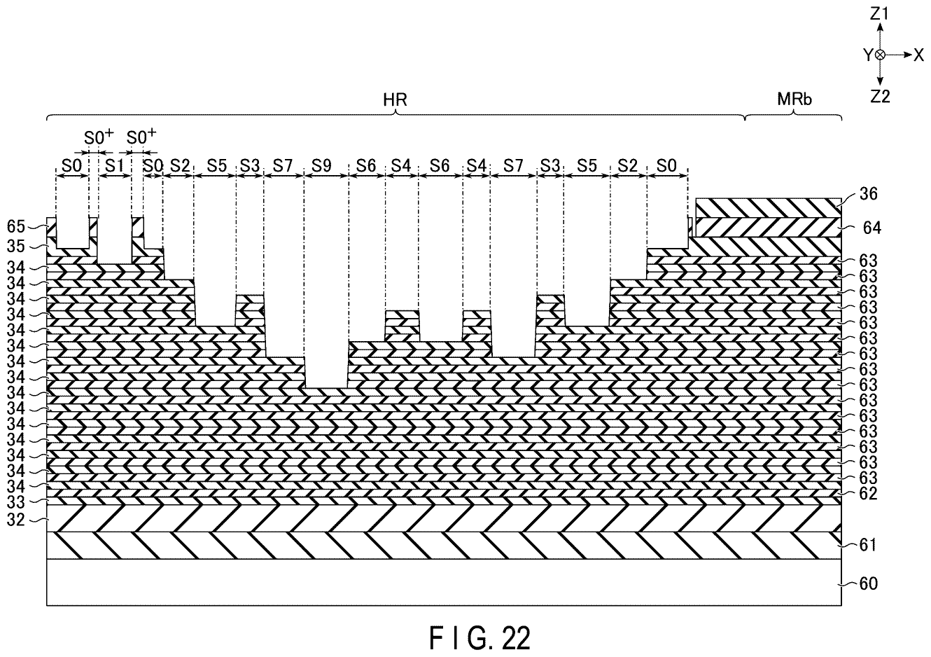

Next, as illustrated in FIGS. 21 and 22, a region including the terrace portions of the word lines WL7, WL5, WL8, WL10, WL0, and WL2 and the select gate line SGS is etched. Specifically, in the region including the terrace portions of the word lines WL7, WL5, WL8, WL10, WL0, and WL2, and the select gate line SGS, the insulating layer 34 and the sacrificial layer 63 for four-steps height (for four-steps height including the uppermost insulating layer 35 in a partial region) are removed. As a result, the region including the terrace portions of the word lines WL10 and WL2 forms a region S4, and is made lower in the Z2 direction by four-steps height with respect to the region S0. The region including the terrace portions of the word lines WL8 and WL0 forms a region S6, and is made lower in the Z2 direction by six-steps height with respect to the region S0. The region including the terrace portions of the word line WL7 and the select gate line SGS forms a region S7, and is made lower in the Z2 direction by seven-steps height with respect to the region S0. The region including the terrace portion of the word line WL5 forms a region S9, and is made lower in the direction Z2 by nine-steps height with respect to the region S0.

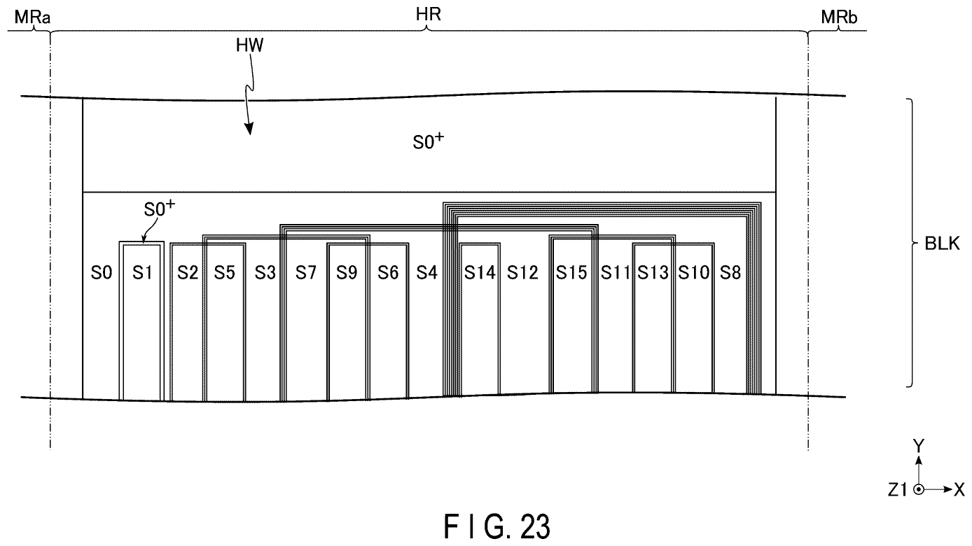

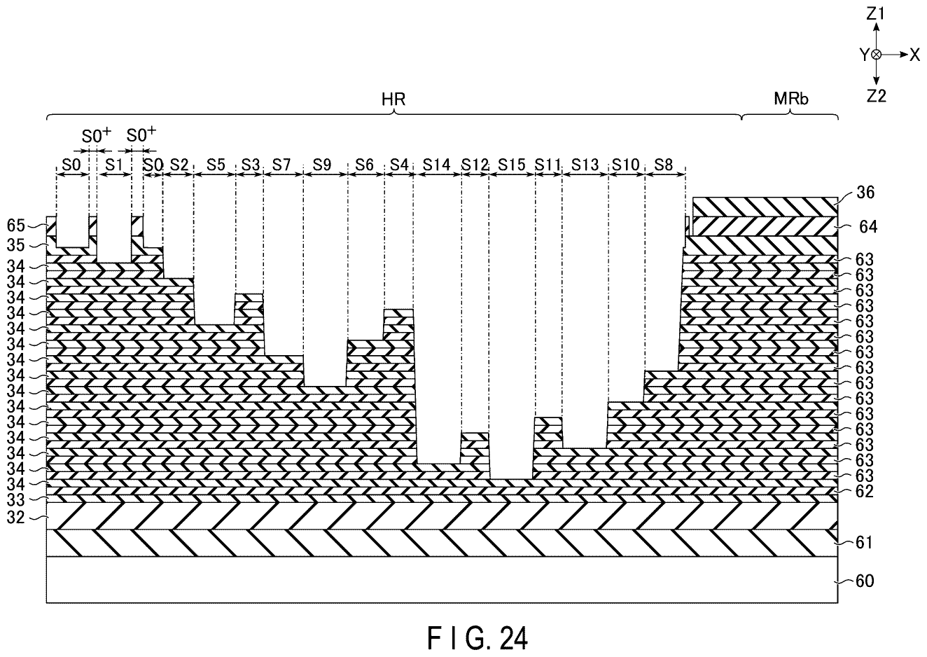

Next, as illustrated in FIGS. 23 and 24, a region including the terrace portions of the word lines WL0 and WL2, the select gate line SGS, the word lines WL3, WL1, WL4, and WL6 is etched. Specifically, in the region including the terrace portions of the word lines WL0 and WL2, the select gate line SGS, the word lines WL3, WL1, WL4, and WL6, the insulating layers 34 and the sacrificial layers 63 for eight-steps height (for eight-steps height including the uppermost insulating layer 35 in a partial region) are removed. As a result, the region including the terrace portion of the word line WL0 forms a region S14, and is made lower in the Z2 direction by fourteen-steps height with respect to the region S0. The region including the terrace portion of the word line WL2 forms a region S12, and is made lower in the Z2 direction by twelve-steps height with respect to the region S0. The region including the terrace portion of the select gate line SGS forms a region S15, and is made lower in the Z2 direction by fifteen-steps height with respect to the region S0. The region including the terrace portion of the word line WL3 forms a region S11, and is made lower in the Z2 direction by eleven-steps height with respect to the region S0. The region including the terrace portion of the word line WL1 forms a region S13, and is made lower in the Z2 direction by thirteen-steps height with respect to the region S0. The region including the terrace portion of the word line WL4 forms a region S10, and is made lower in the Z2 direction by ten-steps height with respect to the region S0. The region including the terrace portion of the word line WL6 forms a region S8, and is made lower in the Z2 direction by eight-steps height with respect to the region S0.

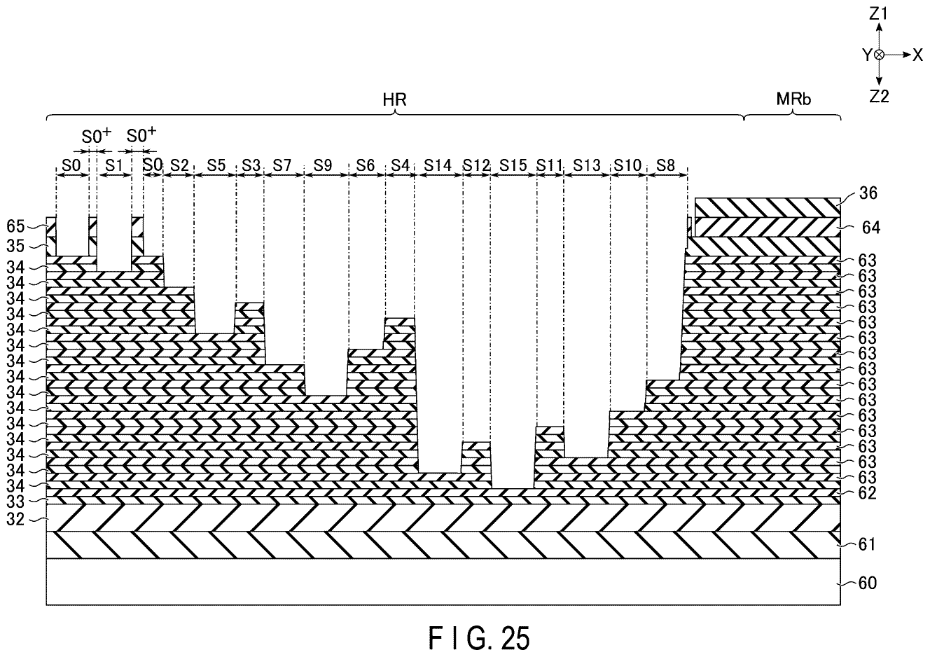

Next, as illustrated in FIG. 25, a portion of the insulating layer 35 exposed on the upper surface of the region S0 and the insulating layer 34 exposed on the upper surface of each of the regions S1 to S15 are selectively removed. As a result, the sacrificial layer 63 is exposed on the upper surface of each of the regions S0 to S14. The sacrificial layer 62 is exposed on the upper surface of the region S15. Since the stop layer 65 is provided on the upper surface of the region S0⁺, the insulating layer 35 provided in the region S0⁺ is not removed.

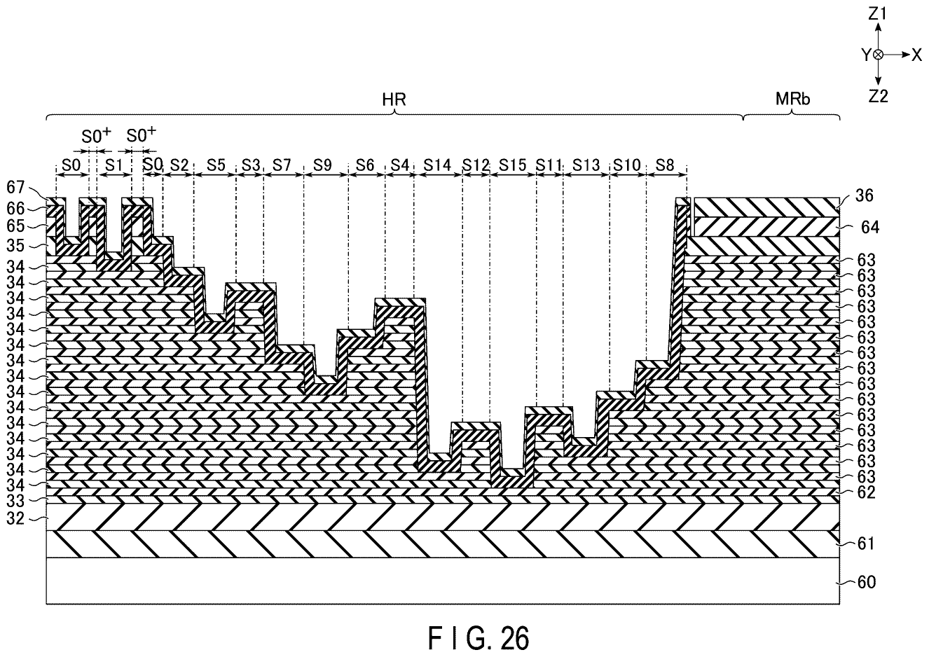

Next, as illustrated in FIG. 26, the sacrificial layer 66 and the insulating layer 67 are provided over the regions S0⁺ and S0 to S15. The sacrificial layer 66 includes, for example, silicon nitride. The insulating layer 67 includes, for example, silicon oxide. The sacrificial layer 66 is provided with the same film thickness on the upper surface of each region and the side surface constituting the step between the regions. On the other hand, the insulating layer 67 is provided so that the film thickness of the side surface is significantly reduced by repeating film formation and etch-back. As described above, the height of the step between the regions is two or more-steps height. Therefore, the film thickness of the insulating layer 67 can be significantly different between the upper surface and the side surface of each region.

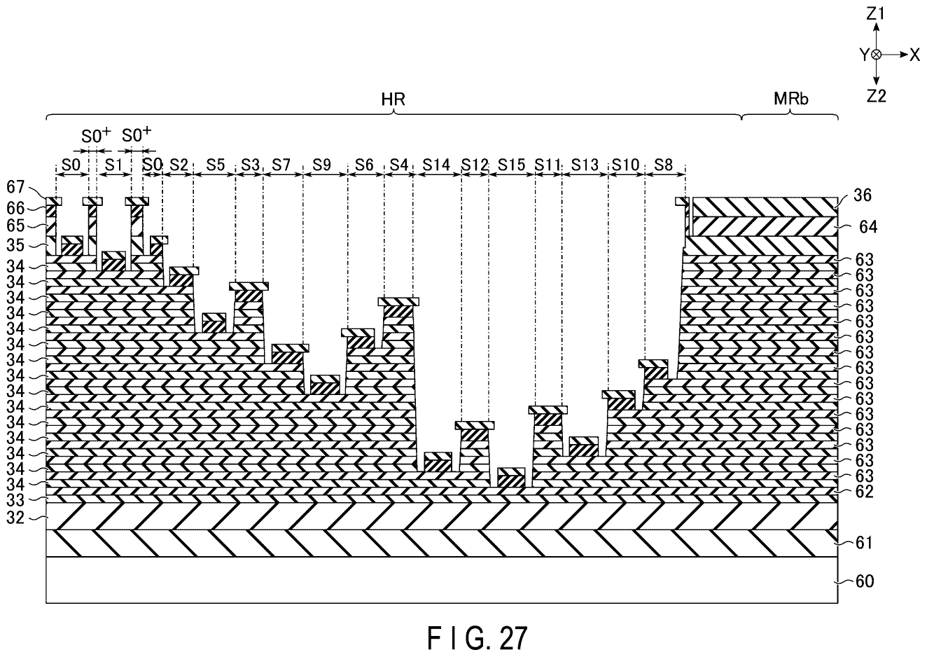

Next, as illustrated in FIG. 27, a part of the insulating layer 67 is removed by, for example, wet etching. As a result, the sacrificial layer 66 is exposed on the side surface constituting the step between the regions. Thereafter, for example, the portion of the sacrificial layer 66 provided on the side surface constituting the step between the regions is removed by wet etching. In the sacrificial layer 66, a portion provided on the upper surface of each region remains away from the side surface. The sacrificial layer 66 remaining on the upper surface of each region corresponds to a thick film portion of the terrace portion of the wiring layer.

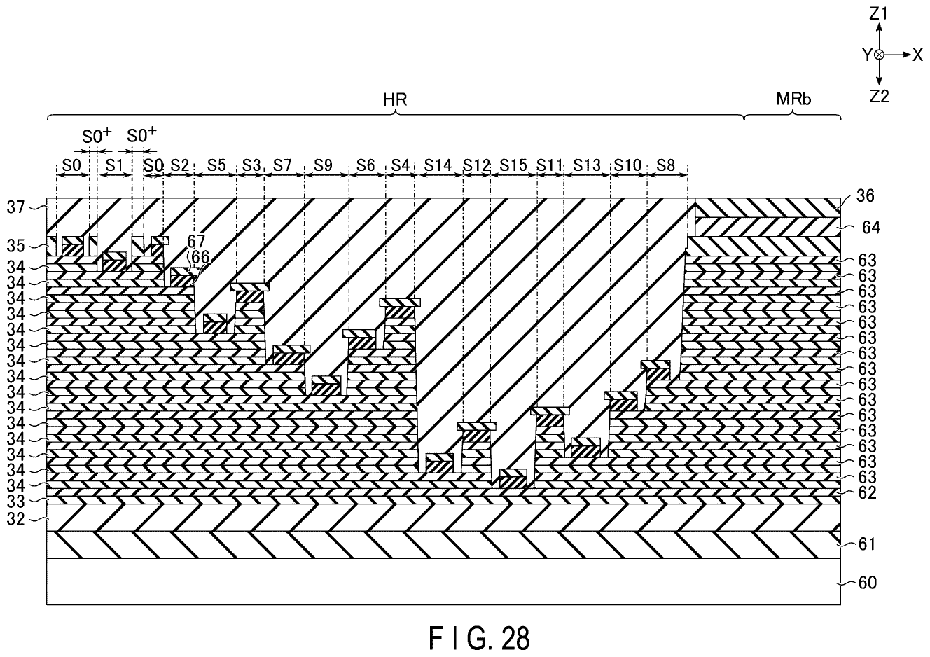

Next, as illustrated in FIG. 28, the insulating layer 67, the sacrificial layer 66, and the stop layer 65 remaining in the region S0⁺ are removed. The regions S0⁺ and S0 to S15 are then covered by the insulating layer 37.

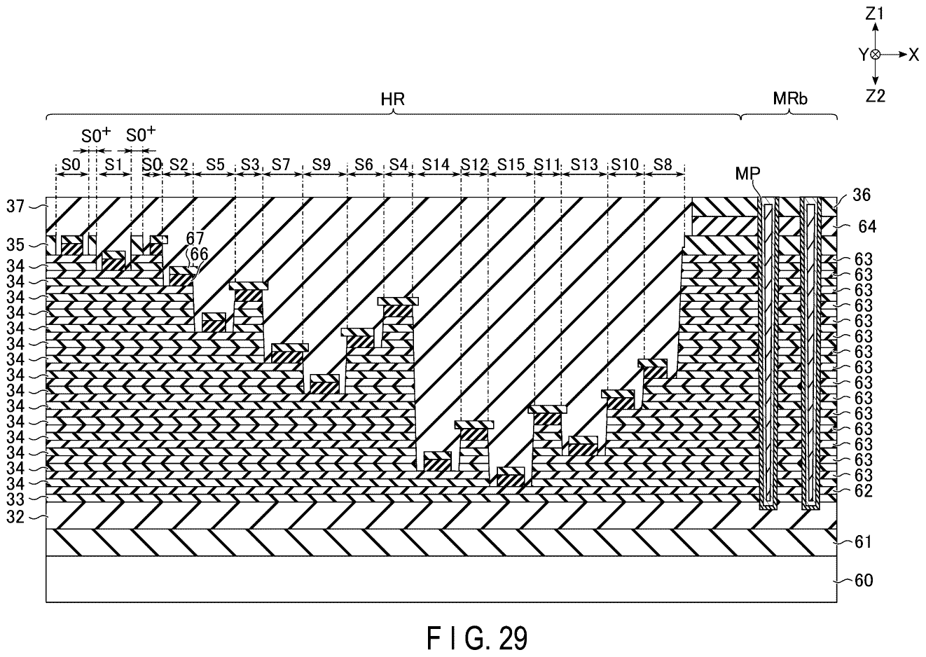

Next, as illustrated in FIG. 29, the memory pillars MP are provided in the memory region MRb and the memory region MRa (not illustrated). Specifically, a plurality of holes is provided in a region where the memory pillars MP are formed. Each hole reaches the insulating layer 32. Each hole is embedded by providing the stacked film 43, the semiconductor film 42, and the core film 41 in this order in each hole. At this point, the stacked film 43 is provided between the semiconductor film 42 and the insulating layer 32.

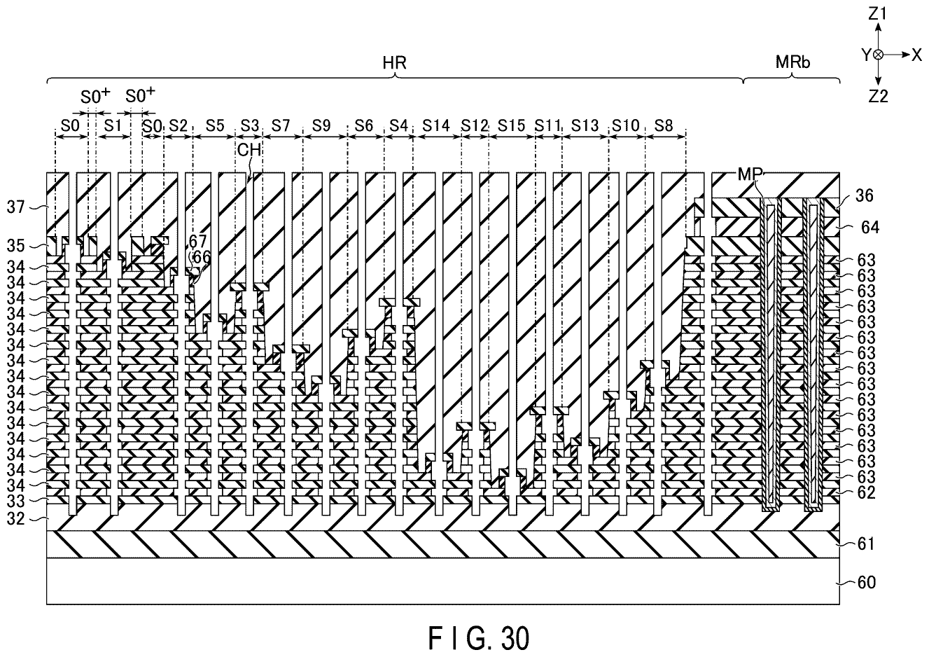

Next, as illustrated in FIG. 30, a plurality of holes CH corresponding to the contacts CC is provided in the hookup region HR. Each hole CH reaches the insulating layer 32. As a result, the sacrificial layers 62, 63, 64, and 66 are exposed in each hole CH. Thereafter, for example, portions of the sacrificial layers 62, 63, 64, and 66 are removed via the holes CH by wet etching. As a result, in each hole CH, recesses are formed in portions where the sacrificial layers 62, 63, 64, and 66 are exposed. Of those formed recesses, the recess formed in the portion where sacrificial layer 62 or 63 and sacrificial layer 66 are stacked and the recess formed in sacrificial layer 64 are larger than the other recesses (that is, recesses formed in portions of sacrificial layers 62 and 63 not stacked with sacrificial layer 66) in the Z direction.

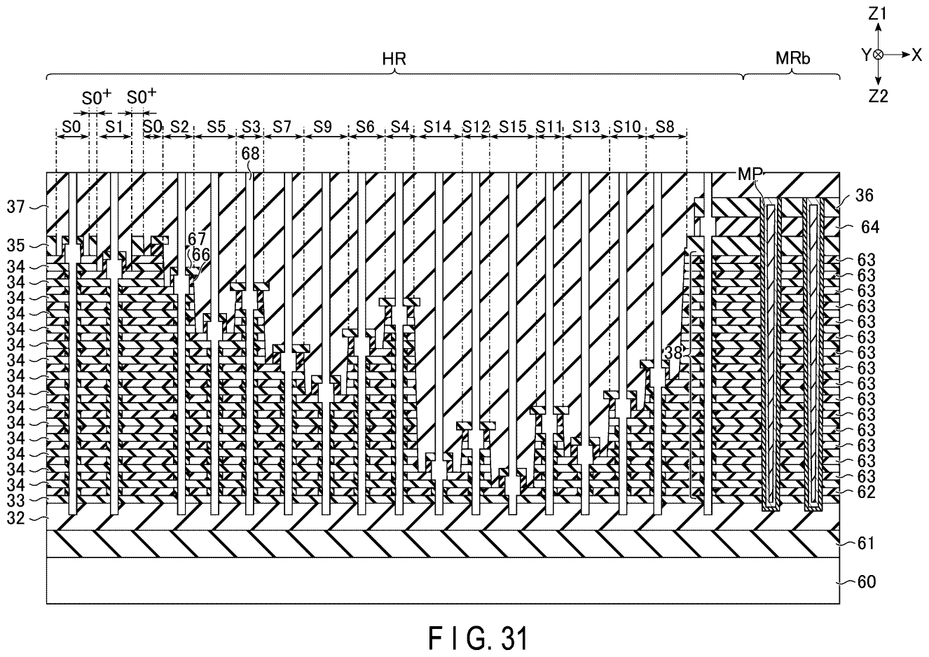

Next, as illustrated in FIG. 31, the insulating film 38 is provided in each hole CH. The insulating film 38 fills a recess formed in a portion of the recess in each hole CH not stacked with the sacrificial layer 66 of the sacrificial layers 62 and 63. On the other hand, the recess formed in the portion where sacrificial layer 62 or 63 and sacrificial layer 66 are stacked is not buried by insulating film 38. Thereafter, by etching back the insulating film 38, the insulating film 38 provided in the recess of the portion where the sacrificial layer 62 or 63 and the sacrificial layer 66 are stacked is removed. On the other hand, the insulating film 38 that fills the recess of the portion of the sacrificial layers 62 and 63 not stacked with the sacrificial layer 66 remains in a state where the recess is filled. After the insulating film 38 is etched back, each hole CH is buried by the sacrificial film 68. The sacrificial film 68 includes, for example, amorphous silicon.

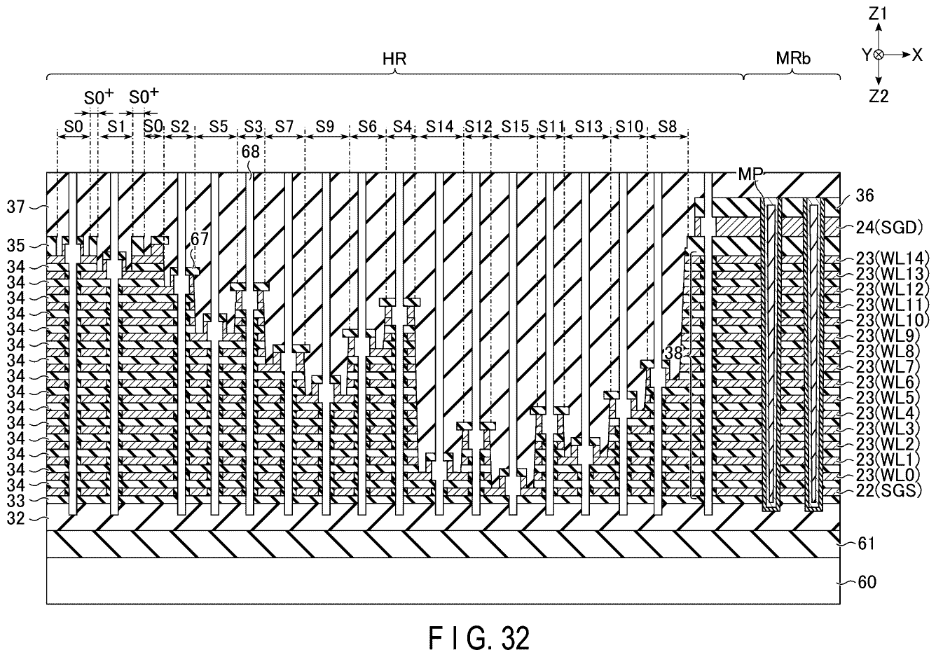

Next, as illustrated in FIG. 32, a replacement process of the sacrificial layers 62, 63, 64, and 66 is executed to form the stacked wiring structure. Specifically, slits are formed in a region where the members SLT are to be formed. The slits reach, for example, the insulating layer 32. Then, the sacrificial layers 62, 63, 64, and 66 are removed via the slits by wet etching with hot phosphoric acid or the like. The electrical conductor is then embedded through the slits into the space from which the sacrificial layers 62, 63, 64, and 66 have been removed.

Thereafter, the conductors formed inside the slits are etched back, and the conductors formed in the adjacent wiring layers are separated. As a result, the wiring layer 22 functioning as the select gate line SGS, the wiring layers 23 functioning as the word lines WL0 to WL14, and the wiring layers 24 functioning as the select gate lines SGD are formed. The wiring layers 22 to 24 formed in this step may contain a barrier metal. In this case, in the formation of the conductors after the sacrificial layers 62, 63, 64, and 66 are removed, for example, titanium nitride is deposited as a barrier metal, and then tungsten is formed.

Next, as illustrated in FIG. 33, the contacts CC are formed. Specifically, the holes CH are opened again by removing the sacrificial film 68. Then, the holes CH are embedded by the conductors. Thereafter, the structure on the Z1 direction side from the contact CV, the layer M0, and the layer M0 is formed, whereby the manufacturing of the memory chip 100 is completed.

Next, as illustrated in FIG. 34, the memory chip 100 and a separately manufactured circuit chip 200 are bonded. Then, the substrate 60 of the memory chip 100 and the insulating layer 61 are removed. As a result, the insulating layer 32 is exposed.

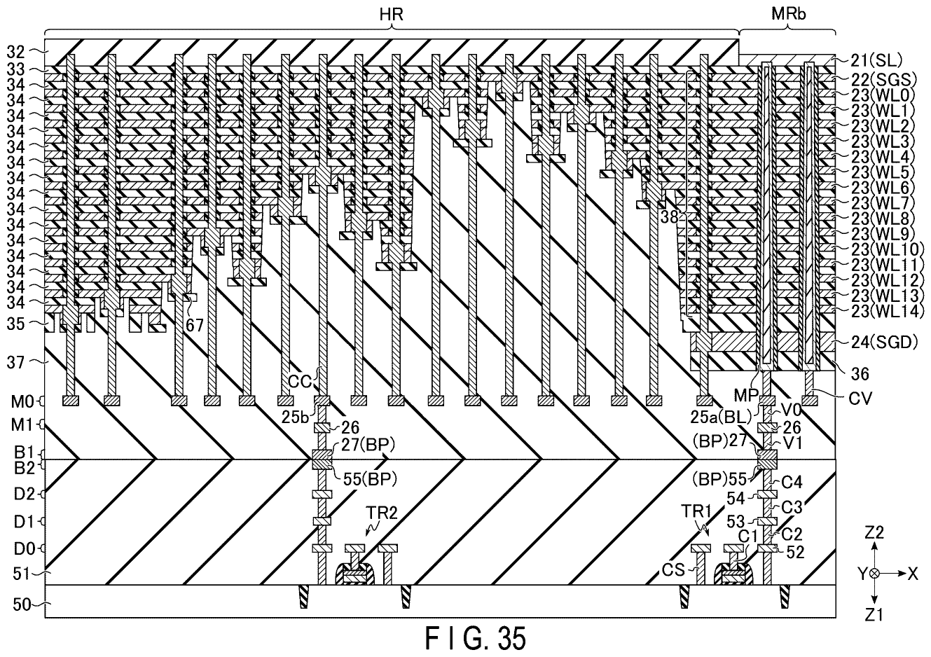

Next, as illustrated in FIG. 35, portions of the insulating layer 32 corresponding to the memory regions MRa and MRb are removed. As a result, a portion of the stacked film 43 of the memory pillar MP located on the Z2 direction side with respect to the insulating layer 33 is exposed. Furthermore, by removing the exposed portion of the stacked film 43, a portion of the semiconductor film 42 located on the Z2 direction side with respect to the insulating layer 33 is exposed. Thereafter, the semiconductor layer 21 is formed over the memory regions MRa and MRb. The semiconductor layer 21 contains, for example, an N-type impurity, and is crystallized by laser annealing treatment to obtain conductivity. Thus, the semiconductor layer 21 functions as the source line SL.

Thereafter, the pad electrode, the protective layer 30, and the like are formed above the semiconductor layer 21 and the insulating layer 32 in the Z2 direction. As described above, the memory device 3 is formed.

### 1.3 Effects According to First Embodiment

According to the first embodiment, the yield of the memory device 3 can be improved. This effect will be described below.

In the formation of the region S1, the stop layer 65, the insulating layer 35, and the uppermost sacrificial layer 63 are etched in the region S0⁺. As a result, the height of the step formed between the region S0⁺ and the region S1 can be substantially equal to or more than two steps. In addition, the etching processes for two-steps height, three-steps height, four-steps height, and eight-steps height are executed on the region S0 so that the processing regions appropriately overlap in the X direction. As a result, the regions S2 to S15 can be formed such that the height of the step formed between the regions adjacent to each other is equal to or more than two-steps height. Therefore, in a case where the insulating layer 67 is formed, the film thickness on each step of the regions S0 to S15 can be made significantly thinner than the film thickness on the upper surface of the regions S0 to S15. Therefore, it is easy to leave the sacrificial layer 66 on the upper surface of the regions S0 to S15 while dividing the sacrificial layer 66 by each step, and it is possible to suppress the occurrence of defects due to the process of thickening the wiring layers 22 and 23.

### 2. Second Embodiment

A memory device according to a second embodiment will be described. The second embodiment is different from the first embodiment in that two staircase structures are formed in the Y direction. In the following description, a configuration and a manufacturing method different from those of the first embodiment will be mainly described. Description of the same configuration and manufacturing method as those of the first embodiment will be omitted as appropriate.

### 2.1 Configuration

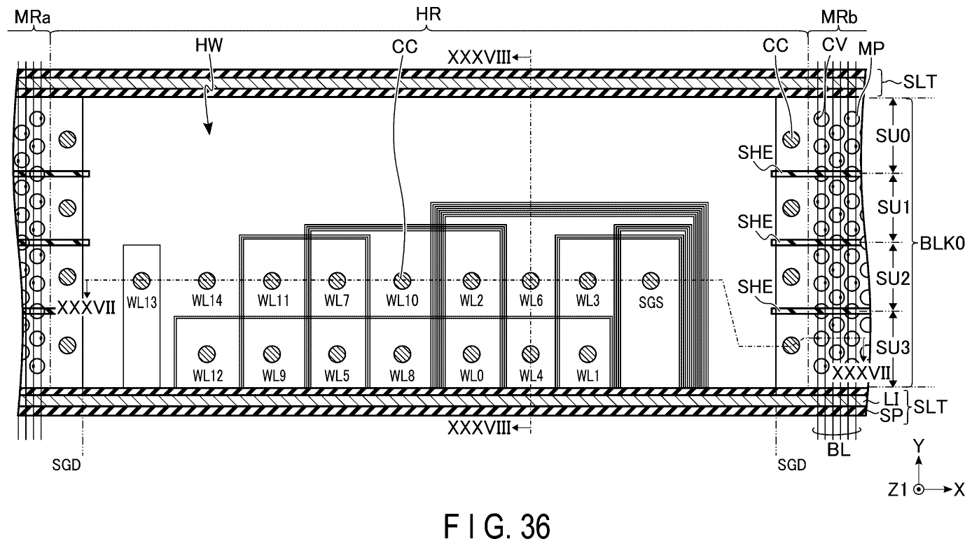

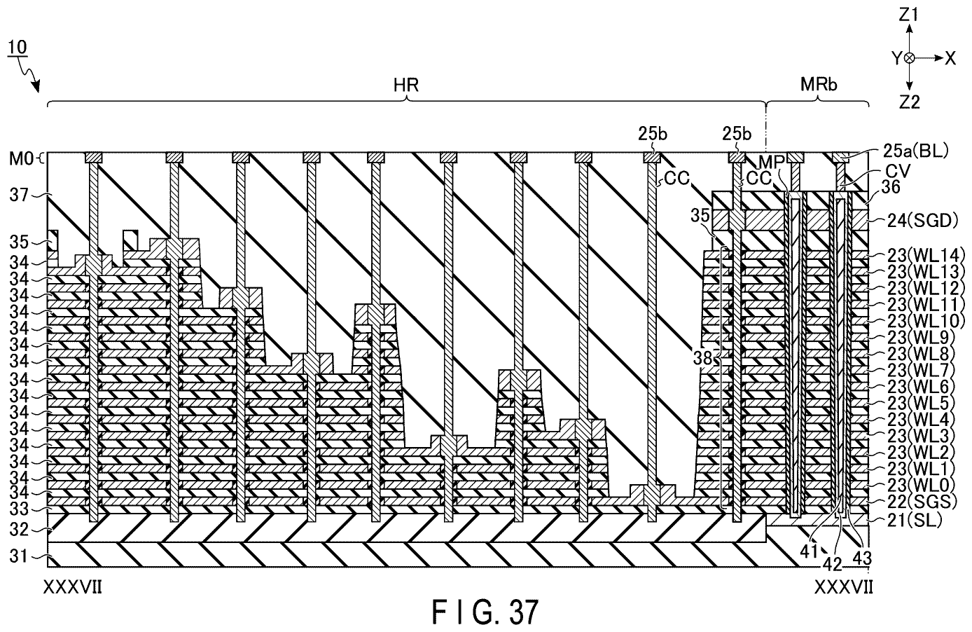

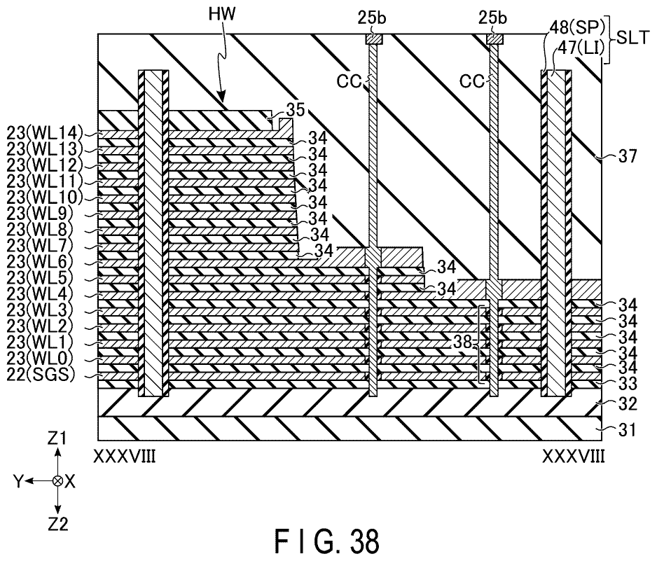

FIG. 36 is a plan view illustrating an example of a planar layout of a memory cell array included in the memory device according to the second embodiment. FIG. 37 is a cross-sectional view taken along a line XXXVII-XXXVII of FIG. 36, illustrating an example of a cross-sectional structure of the memory cell array included in the memory device according to the second embodiment. FIG. 38 is a cross-sectional view taken along a line XXXVIII-XXXVIII in FIG. 36, illustrating an example of a cross-sectional structure of the memory cell array included in the memory device according to the second embodiment. FIGS. 36, 37, and 38 correspond to FIGS. 4, 5, and 6 in the first embodiment, respectively.

As illustrated in FIGS. 36, 37, and 38, in a hookup region HR, terrace portions of respective wiring layers excluding a select gate line SGD are arranged such that groups arranged in the X direction are arranged in two rows in the Y direction. Specifically, the terrace portions of word lines WL14, WL11, WL7, WL10, WL2, WL6, and WL3 are arranged in this order in the X direction. In addition, the terrace portions of the word lines WL14, WL11, WL7, WL10, WL2, WL6, and WL3 are aligned in the X direction in this order so as to be aligned in the Y direction with the terrace portions of word lines WL12, WL9, WL5, WL8, WL0, WL4, and WL1. The terrace portions of the word lines WL12, WL9, WL5, WL8, WL0, WL4, and WL1 are in contact with a member SLT. Then, the terrace portion of a word line WL13 and the terrace portion of a select gate line SGS sandwich the terrace portions arranged in the X direction and the Y direction in the X direction.

The step in the example of FIG. 36 will be specifically described. The word line WL14 forms steps with one-step height, two-steps height, three-steps height, four-steps height, and eight-steps height with the terrace portions of the word lines WL13, WL12, WL11, WL10, and WL6, respectively. The terrace portion of each of the word lines WL12 and WL9 forms a step with three-steps height. The terrace portion of the word line WL11 forms a step with four-steps height with the terrace portion of the word line WL7, and forms a step with two-steps height with the terrace portion of the word line WL9. The terrace portion of each of the word lines WL9 and WL5 forms a step with four-steps height. The terrace portion of the word line WL7 forms a step with three-steps height with the terrace portion of the word line WL10, and forms a step with two-steps height with the terrace portion of the word line WL5. The terrace portion of each of the word lines WL5 and WL8 forms a step with three-steps height. The terrace portion of the word line WL10 forms a step with eight-steps height with the terrace portion of the word line WL2, and forms a step with two-steps height with the terrace portion of the word line WL8. The terrace portion of each of the word lines WL8 and WL0 forms a step with eight-steps height. The terrace portion of the word line WL2 forms a step with four-steps height with the terrace portion of the word line WL6, and forms a step with two-steps height with the terrace portion of the word line WL0. The terrace portion of each of the word lines WL0 and WL4 forms a step with four-steps height. The terrace portion of the word line WL6 forms a step with three-steps height with the terrace portion of the word line WL3, and forms a step with two-steps height with the terrace portion of the word line WL4. The terrace portion of each of the word lines WL4 and WL1 forms a step with three-steps height. The terrace portion of the word line WL3 forms a step with four-steps height with the terrace portion of the select gate line SGS, and forms a step with two-steps height with the terrace portion of the word line WL1. The terrace portion of the select gate line SGS forms a step with fifteen-steps height with the terrace portion of the word line WL14.

As described above, the minimum height of the steps formed between the terrace portions of the select gate line SGS and the word lines WL0 to WL12 and other adjacent terrace portions is two or more-steps height. In other words, between one of the terrace portions of the select gate line SGS and the word lines WL0 to WL12 and each of a plurality of other terrace portions adjacent to the one of the terrace portions as viewed in the Z direction, there is at least one wiring layer other than the two wiring layers having the two adjacent terrace portions. Like the terrace portions of the word lines WL7, WL10, WL2, WL6, and WL3, there are portions where the positions in the Z direction of the five terrace portions arranged adjacent to each other in this order in the X direction are zigzag. In other words, the first and third terrace portions among the five terrace portions arranged in the X direction are located on the same side in the Z direction with respect to the second terrace portion. The third and fifth terrace portions are located on the same side in the Z direction with respect to the fourth terrace portion.

In addition, the terrace portion of the word line WL13 forms a step with one-step height with the terrace portion of the word line WL14. There is a terrace portion of the word line WL14 between the terrace portion of each of the select gate line SGS and the word lines WL0 to WL12 and the terrace portion of the word line WL13. In other words, the terrace portion of the word line WL13 is not adjacent to the terrace portion of each of the select gate line SGS and the word lines WL0 to WL12.

In the second embodiment, the only terrace portion not adjacent to any of the terrace portion of the select gate line SGS and the word lines WL0 to WL12 is the terrace portion of the word line WL13. In this case, each of the terrace portions of the four consecutive wiring layers (that is, the word lines WL13 to WL10) counted from the uppermost word line WL14 is directly adjacent to the terrace portion of the word line WL14.

### 2.2 Manufacturing Method

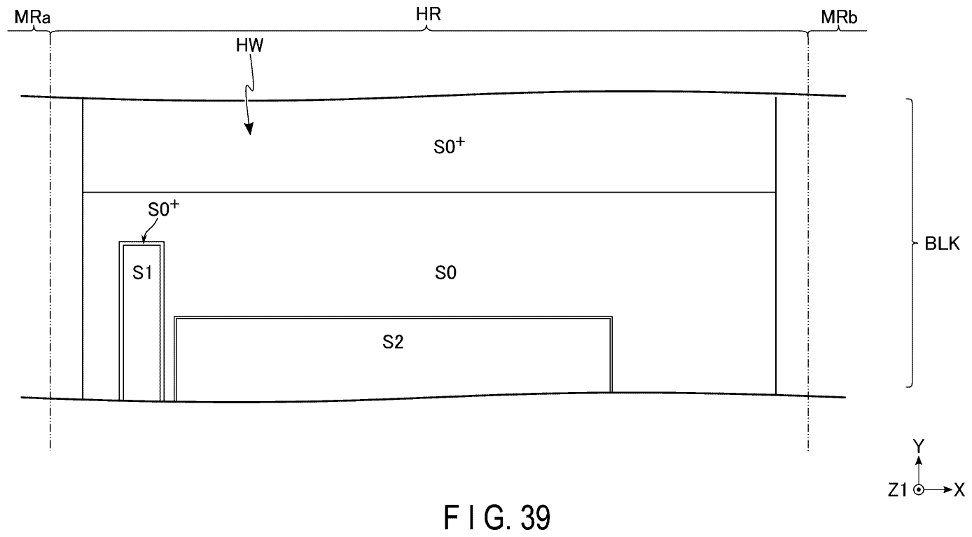

FIGS. 39 to 42 are diagrams illustrating examples of a structure in the process of manufacturing the memory device according to the second embodiment. FIGS. 39 to 42 are planar layouts in the process of manufacturing the memory cell array 10 in the memory chip 100, and correspond to FIG. 36.

First, a structure equivalent to that in FIG. 15 in the first embodiment is formed. The region where the terrace portion of the word line WL13 is to be formed forms the region S1, and is made lower in the Z2 direction by one-step height with respect to the region S0.

Next, as illustrated in FIG. 39, the region including the terrace portions of the word lines WL12, WL9, WL5, WL8, WL0, WL4, and WL1 is etched. Specifically, in the region including the terrace portions of the word lines WL12, WL9, WL5, WL8, WL0, WL4, and WL1, the insulating layer 35, the uppermost sacrificial layer 63, and the insulating layer 34 and the sacrificial layer 63 for one-step height are removed. As a result, the region including the terrace portions of the word lines WL12, WL9, WL5, WL8, WL0, WL4, and WL1 forms a region S2, and is made lower in the Z2 direction by two-steps height with respect to the region S0.

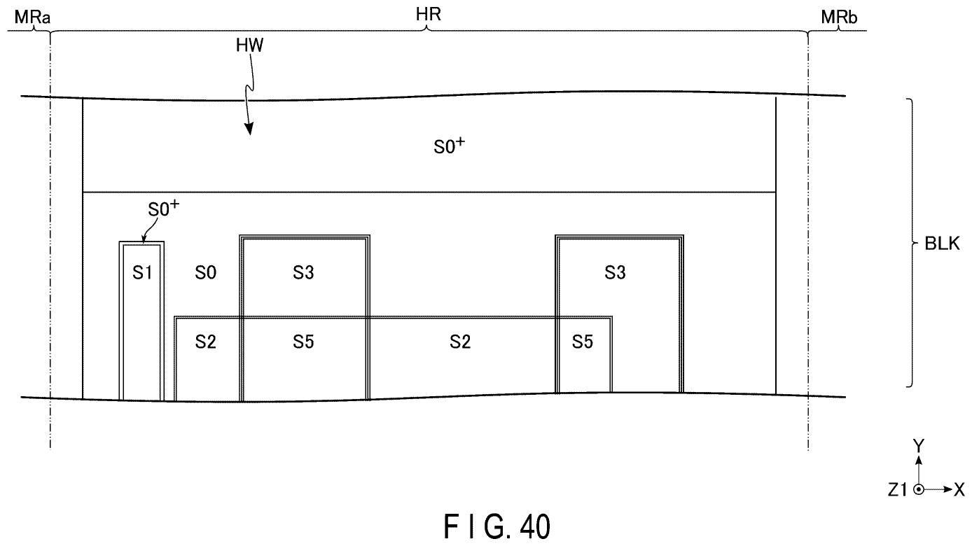

Next, as illustrated in FIG. 40, the region including the terrace portions of the word lines WL11, WL9, WL7, and WL5 and the region including the terrace portions of the word lines WL3, WL1, and the select gate line SGS are etched. Specifically, in each of the region including the terrace portions of the word lines WL11, WL9, WL7, and WL5 and the region including the terrace portions of the word lines WL3, WL1, and the select gate line SGS, the insulating layer 34 and the sacrificial layer 63 for three-steps height (for three-steps height including the uppermost insulating layer 35 in a partial region) are removed. As a result, each of the region including the terrace portions of the word lines WL11 and WL7 and the region including the terrace portions of the word line WL3 and the select gate line SGS forms a region S3, and is made lower in the Z2 direction by three-steps height with respect to the region S0. Each of the region including the terrace portions of the word lines WL9 and WL5 and the region including the terrace portion of the word line WL1 forms a region S5, and is made lower in the Z2 direction by five-steps height with respect to the region S0.

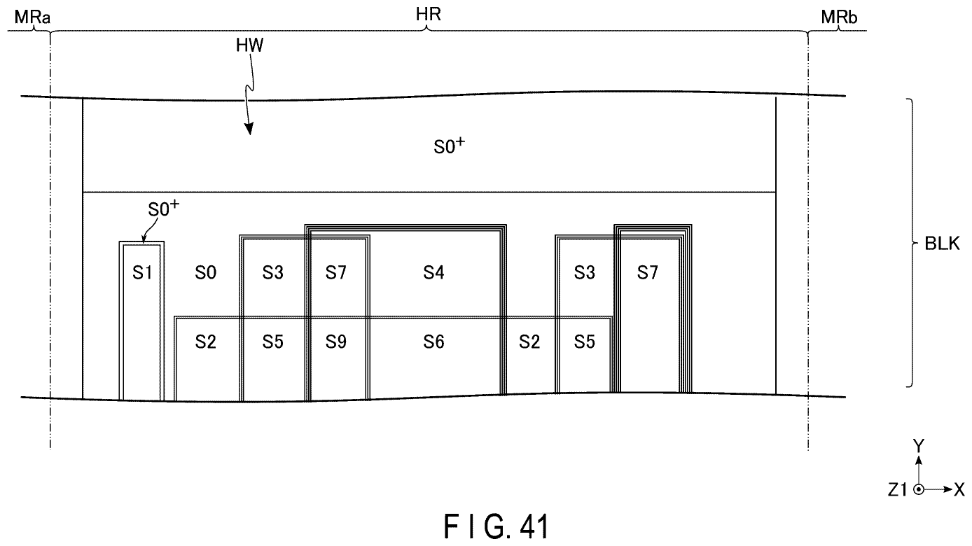

Next, as illustrated in FIG. 41, the region including the terrace portions of the word lines WL7, WL5, WL10, WL8, WL2, and WL0 and the region including the terrace portion of the select gate line SGS are etched. Specifically, in each of the region including the terrace portions of the word lines WL7, WL5, WL10, WL8, WL2, and WL0 and the region including the terrace portion of the select gate line SGS, the insulating layer 34 and the sacrificial layer 63 for four-steps height (for four-steps height including the uppermost insulating layer 35 in a partial region) are removed. As a result, the region including the terrace portions of the word lines WL10 and WL2 forms a region S4, and is made lower in the Z2 direction by four-steps height with respect to the region S0. The region including the terrace portions of the word lines WL8 and WL0 forms a region S6, and is made lower in the Z2 direction by six-steps height with respect to the region S0. Each of the region including the terrace portion of the word line WL7 and the region including the terrace portion of the select gate line SGS forms a region S7, and is made lower in the Z2 direction by seven-steps height with respect to the region S0. The region including the terrace portion of the word line WL5 forms a region S9, and is made lower in the direction Z2 by nine-steps height with respect to the region S0.

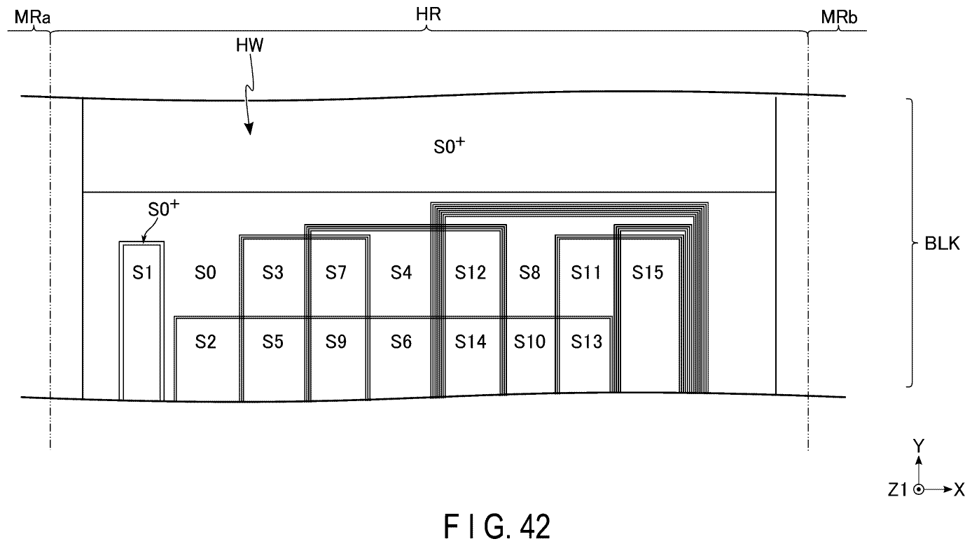

Next, as illustrated in FIG. 42, the region including the terrace portions of the word lines WL2, WL0, WL6, WL4, WL3, WL1, and the select gate line SGS is etched. Specifically, in the region including the terrace portions of the word lines WL2, WL0, WL6, WL4, WL3, WL1, and the select gate line SGS, the insulating layers 34 and the sacrificial layers 63 for eight-steps height (for eight-steps height including the uppermost insulating layer 35 in a partial region) are removed. As a result, the region including the terrace portion of the word line WL2 forms a region S12, and is made lower in the Z2 direction by twelve-steps height with respect to the region S0. The region including the terrace portion of the word line WL0 forms a region S14, and is made lower in the direction Z2 by fourteen-steps height with respect to the region S0. The region including the terrace portion of the word line WL6 forms a region S8, and is made lower in the Z2 direction by eight-steps height with respect to the region S0. The region including the terrace portion of the word line WL4 forms a region S10, and is made lower in the Z2 direction by ten-steps height with respect to the region S0. The region including the terrace portion of the word line WL3 forms a region S11, and is made lower in the Z2 direction by eleven-steps height with respect to the region S0. The region including the terrace portion of the word line WL1 forms a region S13, and is made lower in the Z2 direction by thirteen-steps height with respect to the region S0. The region including the terrace portion of the select gate line SGS forms a region S15, and is made lower in the Z2 direction by fifteen-steps height with respect to the region S0.

Thereafter, the terrace portion is thickened in the same process as in the first embodiment. As described above, the memory device 3 is formed.

### 2.3 Effects According to Second Embodiment

According to the second embodiment, in the formation of the region S1, the stop layer 65, the insulating layer 35, and the uppermost sacrificial layer 63 are etched in the region S0⁺. As a result, it is possible to form a step with substantially two or more-steps height between the region S0⁺ and the region S1. Further, the etching processes for two-steps height, three-steps height, four-steps height, and eight-steps height with respect to the region S0 are executed so that the processing regions appropriately overlap in the X direction and the Y direction. Accordingly, the regions S2 to S15 can be formed such that the step formed between the regions adjacent to each other has two or more-steps height. Therefore, in a case where the insulating layer 67 is formed, the film thickness on each step of the regions S0 to S15 can be made significantly thinner than the film thickness on the upper surface of the regions S0 to S15. Therefore, it is easy to leave the sacrificial layer 66 on the upper surface of the regions S0 to S15 while dividing the sacrificial layer 66 by each step, and it is possible to suppress the occurrence of defects due to the process of thickening the wiring layers 22 and 23.

### 3. Third Embodiment

Next, a memory device according to a third embodiment will be described. The third embodiment is different from the first embodiment in that not only the region S1 but also the region S2 is formed by etching the region S0⁺ directly. In the following description, a configuration and a manufacturing method different from those of the first embodiment will be mainly described. Description of the same configuration and manufacturing method as those of the first embodiment will be omitted as appropriate.

### 3.1 Configuration

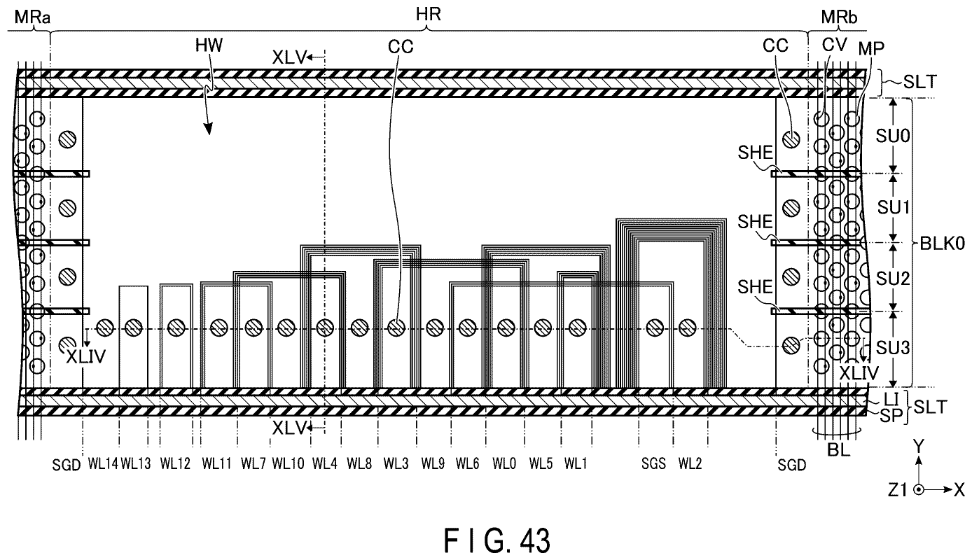

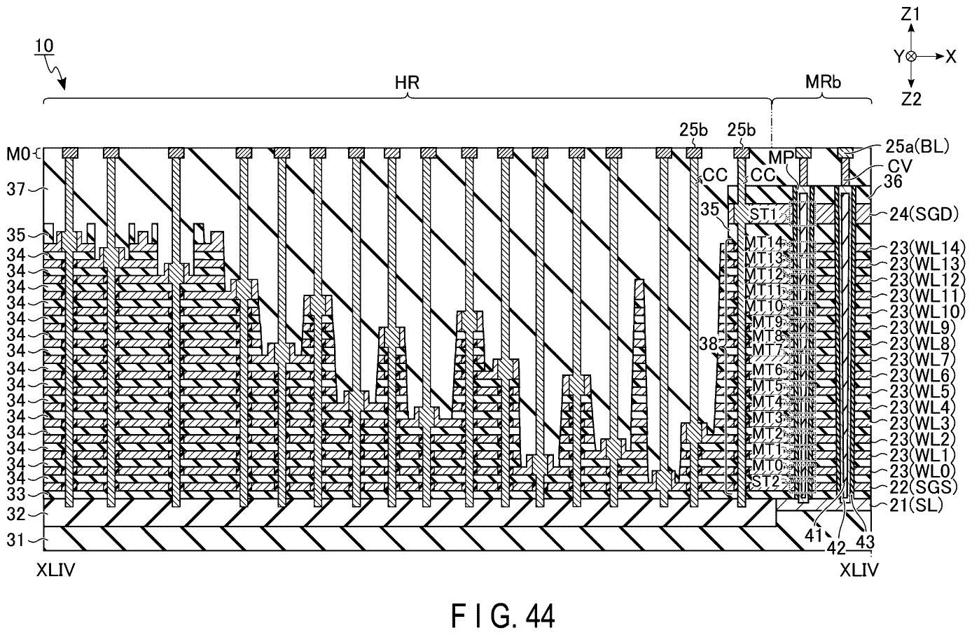

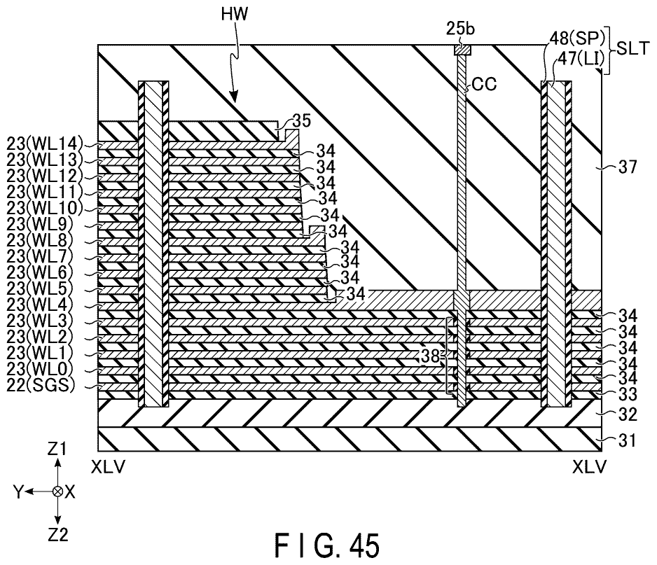

FIG. 43 is a plan view illustrating an example of a planar layout of a memory cell array included in a memory device according to a third embodiment. FIG. 44 is a cross-sectional view taken along a line XLIV-XLIV of FIG. 43, illustrating an example of a cross-sectional structure of the memory cell array included in the memory device according to the third embodiment. FIG. 45 is a cross-sectional view taken along a line XLV-XLV of FIG. 43, illustrating an example of a cross-sectional structure of the memory cell array included in a memory device according to a third embodiment. FIGS. 43, 44, and 45 correspond to FIGS. 4, 5, and 6 in the first embodiment, respectively.

As illustrated in FIGS. 43, 44, and 45, in the hookup region HR, the terrace portions of the respective wiring layers except the select gate line SGD are arranged in the X direction in the order of the word lines WL14, WL13, (WL14), WL12, (WL14), WL11, WL7, WL10, WL4, WL8, WL3, WL9, WL6, WL0, WL5, WL1, and (WL11), the select gate line SGS, and the word lines WL2 and (WL14). Here, the terrace portions with parentheses are terrace portions where contacts CC are not provided.

The step in the example of FIG. 43 will be specifically described. The word line WL14 forms steps with one-step height, two-steps height, three-steps height, four-steps height, five-steps height, six-steps height, and twelve-steps height with the terrace portions of the word lines WL13, WL12, WL11, WL10, WL9, WL8, and WL2, respectively. The terrace portion of each of the word lines WL11 and WL7 forms a step with four-steps height. The terrace portion of each of the word lines WL7 and WL10 forms a step with three-steps height. The terrace portion of each of the word lines WL10 and WL4 forms a step with six-steps height. The terrace portion of each of the word lines WL4 and WL8 forms a step with four-steps height. The terrace portion of each of the word lines WL8 and WL3 forms a step with five-steps height. The terrace portion of each of the word lines WL3 and WL9 forms a step with six-steps height. The terrace portion of each of the word lines WL9 and WL6 forms a step with three-steps height. The terrace portion of each of the word lines WL6 and WL0 forms a step with six-steps height. The terrace portion of each of the word lines WL0 and WL5 forms a step with five-steps height. The terrace portion of each of the word lines WL5 and WL1 forms a step with four-steps height. The terrace portion of each of the select gate line SGS and the word line WL2 forms a step with three-steps height.

As described above, the minimum height of the steps formed between the terrace portion and another terrace portion adjacent to the terrace portion among the select gate line SGS and the word lines WL0 to WL11 is three or more-steps height. In other words, between one of the terrace portions of the select gate line SGS and the word lines WL0 to WL11 and each of a plurality of other terrace portions adjacent to the one of the terrace portions as viewed in the Z direction, there are at least two wiring layers other than the two wiring layers having the two adjacent terrace portions. Like the terrace portions of the word lines WL7 and WL10, WL4, WL8, and WL3, there are portions where the positions in the Z direction of the five terrace portions arranged adjacent to each other in this order in the X direction are zigzag. In other words, the first and third terrace portions among the five terrace portions arranged in the X direction are located on the same side in the Z direction with respect to the second terrace portion. The third and fifth terrace portions are located on the same side in the Z direction with respect to the fourth terrace portion.

In addition, the terrace portions of the word lines WL12 and WL13 form a step with one-step height and a step with two-steps height with the terrace portion of the word line WL14, respectively. There is a terrace portion of the word line WL14 between the terrace portion of each of the select gate line SGS and the word lines WL0 to WL11 and the terrace portion of the word line WL12. Similarly, there is a terrace portion of the word line WL14 between the terrace portion of each of the select gate line SGS and the word lines WL0 to WL11 and the terrace portion of the word line WL13. In other words, the terrace portion of each of the word lines WL13 and WL12 is not adjacent to the terrace portion of each of the select gate line SGS and the word lines WL0 to WL11.

In the third embodiment, the number of terrace portions not adjacent to the terrace portion of each of the select gate line SGS and the word lines WL0 to WL11 is two of the terrace portions of the word lines WL12 and WL13. In this case, each of the terrace portions of the six consecutive wiring layers (that is, the word lines WL13 to WL8) counted from the uppermost word line WL14 is directly adjacent to the terrace portion of the word line WL14.

### 3.2 Manufacturing Method

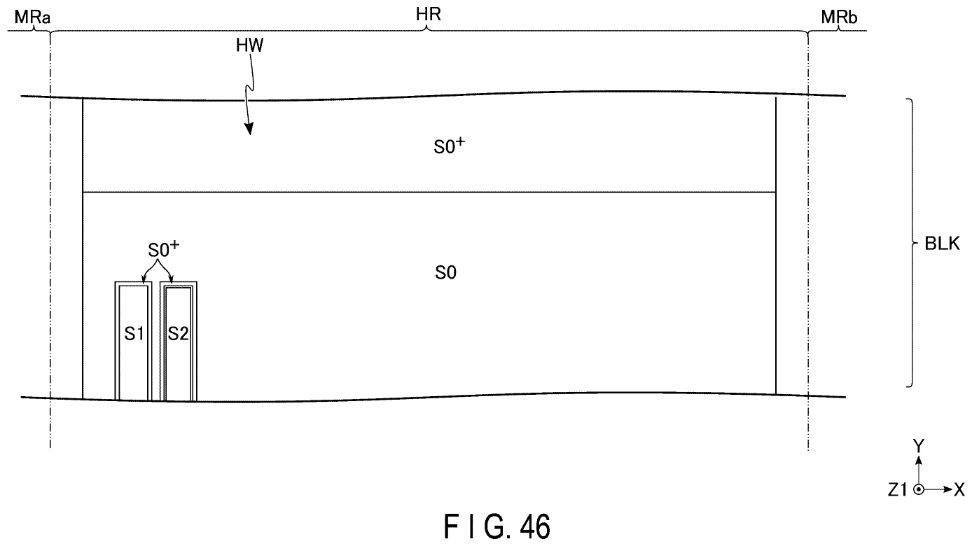

FIGS. 46 to 51 are diagrams illustrating an example of a structure in the process of manufacturing the memory device according to the third embodiment. FIGS. 46 to 51 are planar layouts in the process of manufacturing the memory cell array 10 in the memory chip 100, and correspond to FIG. 43.

First, a structure equivalent to that in FIG. 15 in the first embodiment is formed. The region where the terrace portion of the word line WL13 is to be formed forms the region S1, and is made lower in the Z2 direction by one-step height with respect to the region S0.

Next, as illustrated in FIG. 46, a region where the terrace portion of the word line WL12 is to be formed is etched. Specifically, in the region where the terrace portion of the word line WL12 is to be formed in the region S0⁺, the insulating layer 35, the uppermost sacrificial layer 63, and the insulating layer 34 and the sacrificial layer 63 for one-step height are removed. As a result, the region where the terrace portion of the word line WL12 is to be formed forms a region S2, and is made lower in the Z2 direction by two-steps height with respect to the region S0.

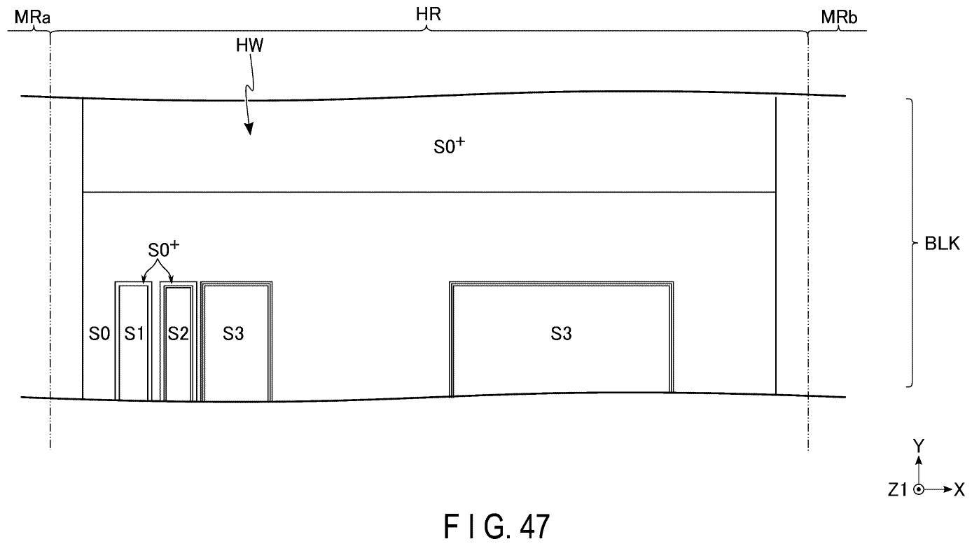

Next, as illustrated in FIG. 47, the region including the terrace portions of the word lines WL11 and WL7 and the region including the terrace portions of the word lines WL6, WL0, WL5, WL1, and the select gate line SGS are etched. Specifically, in each of the region including the terrace portions of the word lines WL11 and WL7 and the region including the terrace portions of the word lines WL6, WL0, WL5, WL1, and the select gate line SGS, the insulating layer 35, the uppermost sacrificial layer 63, and the insulating layer 34 and the sacrificial layer 63 corresponding to two-steps height are removed. As a result, each of the region including the terrace portions of the word lines WL11 and WL7 and the region including the terrace portions of the word lines WL6, WL0, WL5, WL1, and the select gate line SGS forms a region S3, and is made lower in the Z2 direction by three-steps height with respect to the region S0.

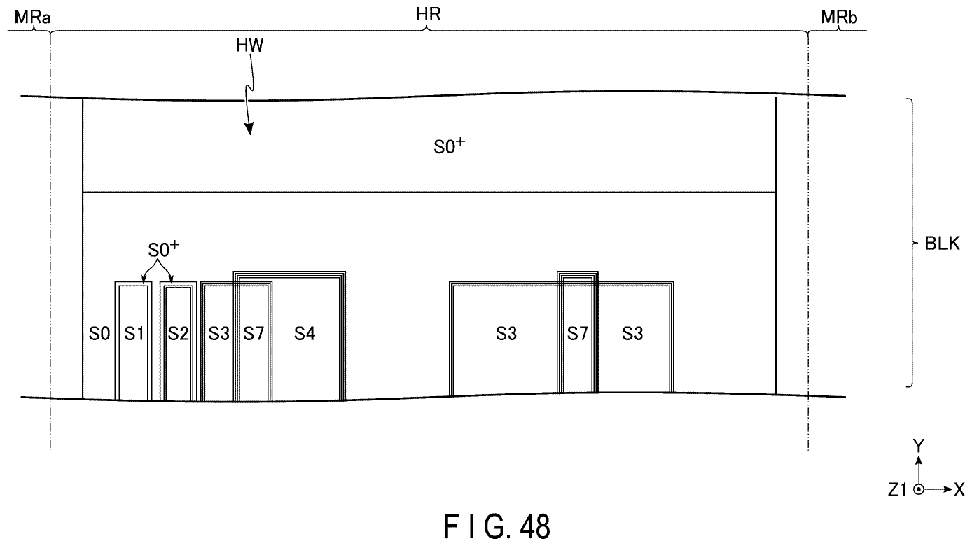

Next, as illustrated in FIG. 48, the region including the terrace portions of the word lines WL7, WL10, and WL4 and the region including the terrace portion of the word line WL1 are etched. Specifically, in each of the region including the terrace portions of the word lines WL7, WL10, and WL4 and the region including the terrace portion of the word line WL1, the insulating layers 34 and the sacrificial layers 63 for four-steps height (for four-steps height including the uppermost insulating layer 35 in a partial region) are removed. As a result, the region including the terrace portions of the word lines WL10 and WL4 forms a region S4, and is made lower in the Z2 direction by four-steps height with respect to the region S0. Each of the region including the terrace portion of the word line WL7 and the region including the terrace portion of the word line WL1 forms a region S7, and is made lower in the Z2 direction by seven-steps height with respect to the region S0.

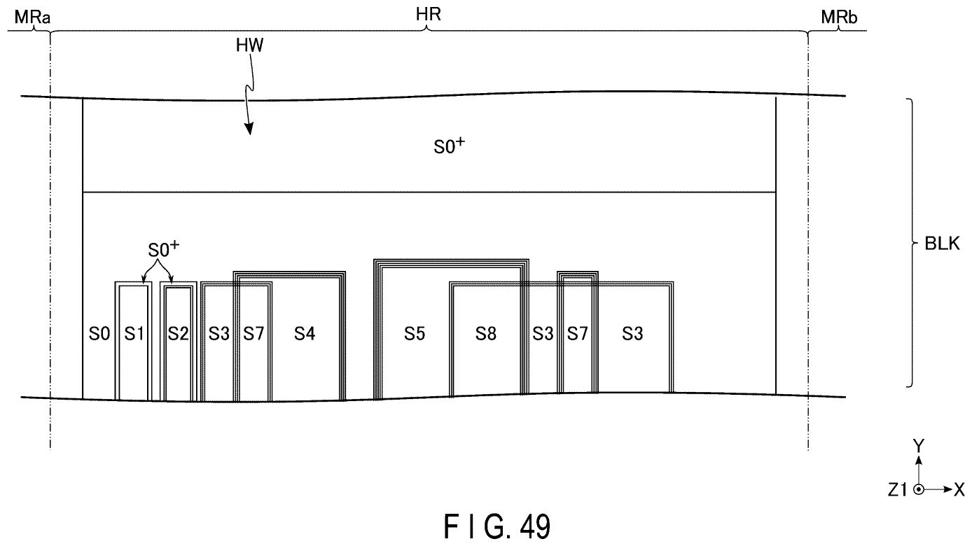

Next, as illustrated in FIG. 49, the region including the terrace portions of the word lines WL3, WL9, WL6, and WL0 is etched. Specifically, in the region including the terrace portions of the word lines WL3, WL9, WL6, and WL0, the insulating layer 34 and the sacrificial layer 63 for five-steps height (for five-steps height including the uppermost insulating layer 35 in a partial region) are removed. As a result, the region including the terrace portions of the word lines WL3 and WL9 forms a region S5, and is made lower in the Z2 direction by five-steps height with respect to the region S0. The region including the terrace portions of the word lines WL6 and WL0 forms a region S8, and is made lowered in the Z2 direction by eight-steps height with respect to the region S0.

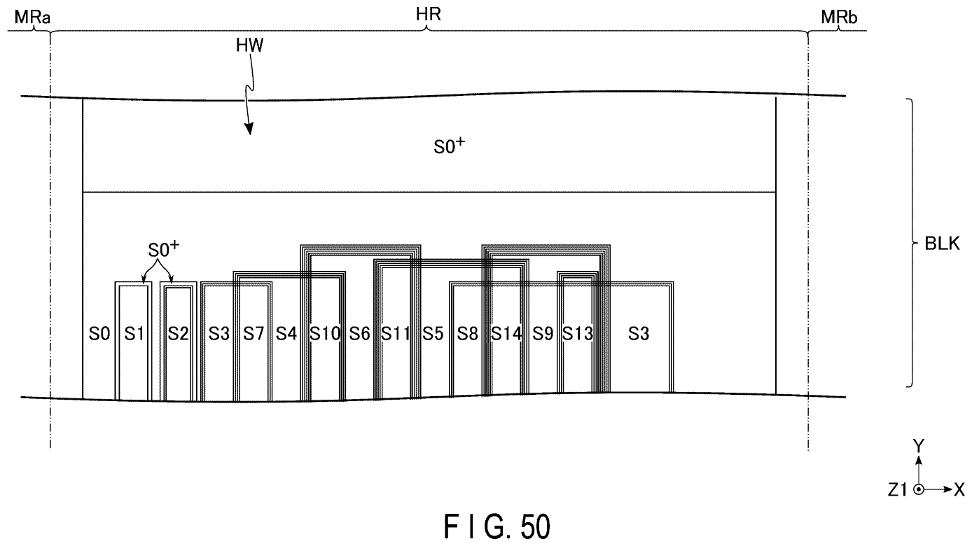

Next, as illustrated in FIG. 50, the region including the terrace portions of the word lines WL4, WL8, and WL3 and the region including the terrace portions of the word lines WL0, WL5, and WL1 are etched. Specifically, in each of the region including the terrace portions of the word lines WL4, WL8, and WL3 and the region including the terrace portions of the word lines WL0, WL5, and WL1, the insulating layer 34 and the sacrificial layer 63 for six-steps height (for six-steps height including the uppermost insulating layer 35 in a partial region) are removed. As a result, the region including the terrace portion of the word line WL8 forms a region S6, and is made lower in the Z2 direction by six-steps height with respect to the region S0. The region where the word line WL5 is to be provided forms a region S9, and is made lower in the direction Z2 by nine-steps height with respect to the region S0. The region including the terrace portion of the word line WL4 forms a region S10, and is made lower in the Z2 direction by ten-steps height with respect to the region S0. The region including the terrace portion of the word line WL3 forms a region S11, and is made lower in the Z2 direction by eleven-steps height with respect to the region S0. The region including the terrace portion of the word line WL1 forms a region S13, and is made lower in the Z2 direction by thirteen-steps height with respect to the region S0. The region including the terrace portion of the word line WL0 forms a region S14, and is made lower in the direction Z2 by fourteen-steps height with respect to the region S0.

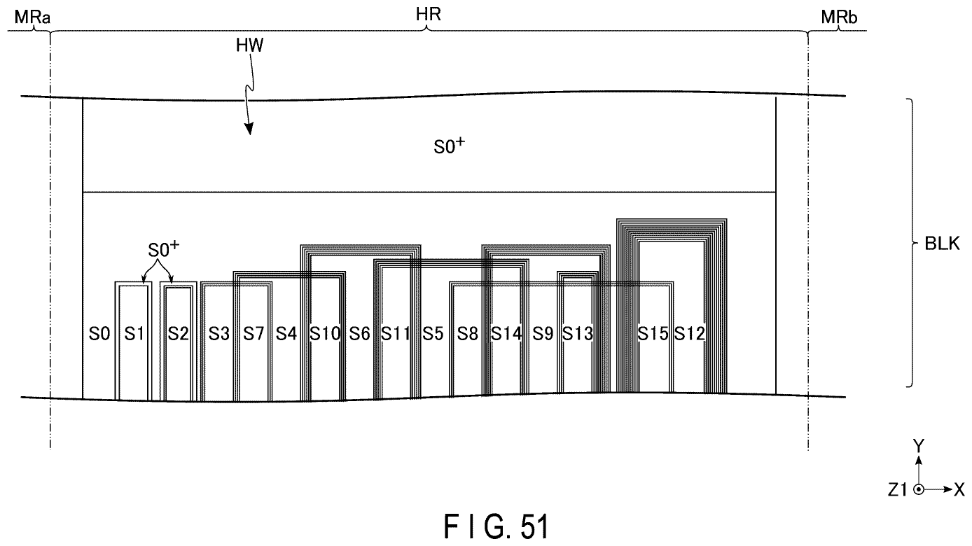

Next, as illustrated in FIG. 51, the region including the terrace portions of the select gate line SGS and the word line WL2 is etched. Specifically, in the region including the terrace portions of the select gate line SGS and the word line WL2, the insulating layer 34 and the sacrificial layer 63 for twelve-steps height (for twelve-steps height including the uppermost insulating layer 35 in a partial region) are removed. As a result, the region including the terrace portion of the select gate line SGS forms a region S15, and is made lower in the Z2 direction by fifteen-steps height with respect to the region S0. The region including the terrace portion of the word line WL2 forms a region S12, and is made lower in the Z2 direction by twelve-steps height with respect to the region S0.

Thereafter, the terrace portion is thickened in the same process as in the first embodiment. As described above, the memory device 3 is formed.

### 3.3 Effects According to Third Embodiment

According to the third embodiment, in the formation of the region S1, the stop layer 65, the insulating layer 35, and the uppermost sacrificial layer 63 are etched in the region S0⁺. As a result, it is possible to form a step with substantially two or more-steps height between the region S0⁺ and the region S1. In the formation of the region S2, the stop layer 65, the insulating layer 35, the uppermost sacrificial layer 63, the uppermost insulating layer 34, and the second upper sacrificial layer 63 are etched in the region S0⁺. As a result, it is possible to form a step with substantially three or more-steps height between the region S0⁺ and the region S2. Further, the etching processes for three-steps height, four-steps height, five-steps height, six-steps height, and twelve-steps height are executed in the region S0 so that the processing regions appropriately overlap in the X direction. Accordingly, the regions S3 to S15 can be formed such that the steps formed between the regions adjacent to each other have three or more-steps height. Therefore, in a case where the insulating layer 67 is formed, the film thickness on each step of the regions S0 to S15 can be made significantly thinner than the film thickness on the upper surface of the regions S0 to S15. Therefore, it is easy to leave the sacrificial layer 66 on the upper surface of the regions S0 to S15 while dividing the sacrificial layer 66 by each step, and it is possible to suppress the occurrence of defects due to the process of thickening the wiring layers 22 and 23.

In the third embodiment, for convenience of description, the case where the number of stacked select gate lines SGS and word lines WL is 15 has been described, but the present invention is not limited thereto. For example, as described above, the manufacturing method of executing the etching processes for three-steps height, four-steps height, five-steps height, six-steps height, and twelve-steps height on the region S0 can be applied up to a case where the number of stacked layers including select gate lines SGS and word lines WL is twenty seven.

### 4. Fourth Embodiment

Next, a memory device according to a fourth embodiment will be described. The fourth embodiment is different from the first embodiment in that between the terrace portions provided with the contact CC a terrace portion (protrusion portion) located above these terrace portions and not provided with the contact CC is formed. In the following description, a configuration and a manufacturing method different from those of the first embodiment will be mainly described. Description of the same configuration and manufacturing method as those of the first embodiment will be omitted as appropriate.

### 4.1 Configuration

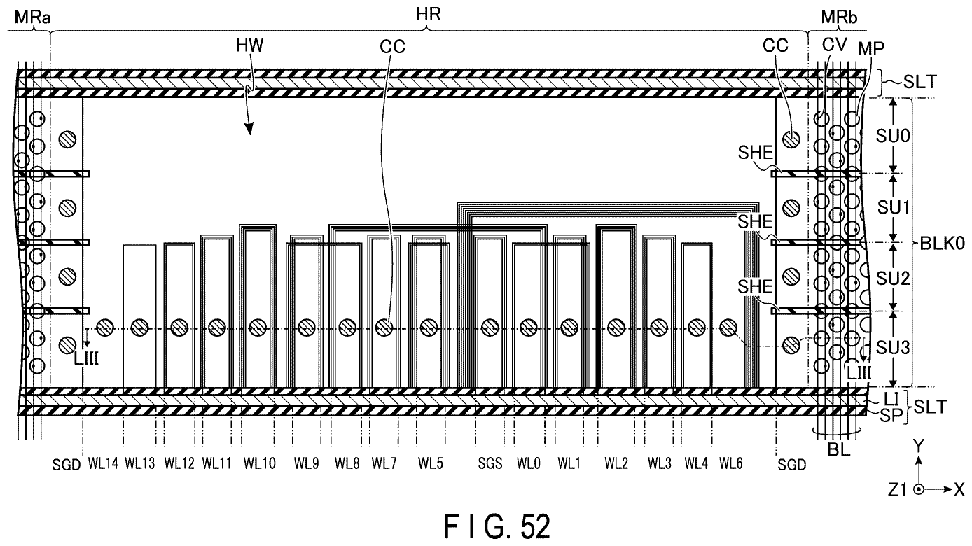

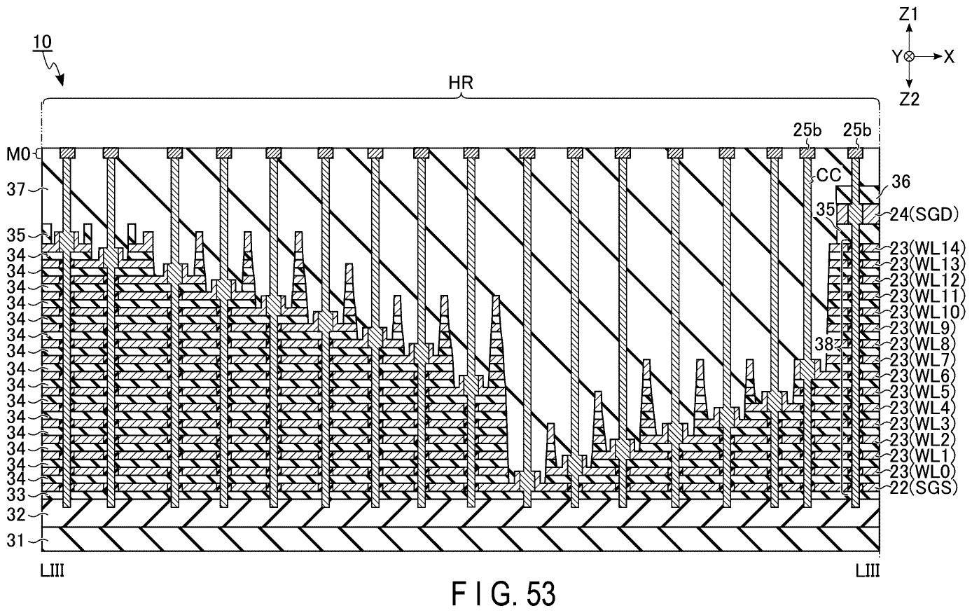

FIG. 52 is a plan view illustrating an example of a planar layout of a memory cell array included in the memory device according to the fourth embodiment. FIG. 53 is a cross-sectional view taken along a line LIII-LIII of FIG. 52, illustrating an example of a cross-sectional structure of the memory cell array included in the memory device according to the fourth embodiment. FIGS. 52 and 53 correspond to FIGS. 4 and 5 in the first embodiment, respectively. Note that a cross-sectional view taken along the YZ plane is the same as that of the first embodiment, and thus illustration thereof is omitted.

As illustrated in FIGS. 52 and 53, in the hookup region HR, the terrace portions of the wiring layers except the select gate line SGD are arranged in the X direction in the order of the word lines WL14, WL13, (WL14), WL12, (WL14), WL11, (WL14), WL10, (WL14), WL9, (WL12), WL8, (WL10), WL7, (WL10), WL5, and (WL10), the select gate line SGS, and the word lines (WL2), WL0, (WL4), WL1, (WL6), WL2, (WL6), WL3, (WL6), WL4, WL6, and (WL14). Here, the terrace portions with parentheses are terrace portions where contacts CC are not provided.

The step in the example of FIG. 52 will be specifically described. The word line WL14 forms steps with one-step height, two-steps height, three-steps height, four-steps height, and six-steps height with the terrace portions of the word lines WL13, WL12, WL11, WL10, and WL6, respectively. The word line WL12 forms steps with three-steps height and four-steps height with the terrace portions of the word lines WL9 and WL8, respectively. The word line WL10 forms steps with two-steps height, three-steps height, five-steps height, and eleven-steps height with the terrace portions of the word lines WL8, WL7, and WL5 and the select gate line SGS, respectively. The word line WL6 forms steps with two-steps height, three-steps height, four-steps height, and five-steps height with the terrace portions of the word lines WL4, WL3, WL2, and WL1, respectively. The word line WL4 forms steps with three-steps height and four-steps height with the terrace portions of the word lines WL1 and WL0, respectively. The word line WL2 forms steps with two-steps height and three-steps height with the terrace portions of the word line WL0 and the select gate line SGS, respectively.

The terrace portion of the word line WL12 adjacent to the terrace portions of the word lines WL9 and WL8 is provided away from the terrace portion of the word line WL12 in contact with the contact CC. The terrace portion of the word line WL10 adjacent to the terrace portions of the word lines WL8, WL7, and WL5 and the terrace portion of the select gate line SGS is separated from the terrace portion of the word line WL10 in contact with the contact CC. The terrace portion of the word line WL6 adjacent to the terrace portions of the word lines WL3, WL2, and WL1 is separated from the terrace portion of the word line WL6 in contact with the contact CC. The terrace portion of the word line WL4 adjacent to the terrace portions of the word lines WL1 and WL0 is separated from the terrace portion of the word line WL4 in contact with the contact CC. The terrace portion of the word line WL2 adjacent to the terrace portions of the word line WL0 and the select gate line SGS is separated from the terrace portion of the word line WL2 in contact with the contact CC.

As described above, the minimum height of the steps formed between the terrace portion and another terrace portion adjacent to the terrace portion among the select gate line SGS and the word lines WL0 to WL12 is two or more-steps height. In other words, between one of the terrace portions of the select gate line SGS and the word lines WL0 to WL12 and each of a plurality of other terrace portions adjacent to the one of the terrace portions as viewed in the Z direction, there is at least one wiring layer other than the two wiring layers having the two adjacent terrace portions. Like the terrace portions of the word lines WL12, (WL14), WL11, (WL14), and WL10, there are portions where the positions in the Z direction of the five terrace portions (including the terrace portion where the contact CC is not provided) arranged adjacent to each other in this order in the X direction are zigzag. Similarly, there are portions where the positions in the Z direction of the five terrace portions (including the terrace portion where the contact CC is not provided) arranged adjacent to each other in this order in the X direction are zigzag, like the terrace portions of the word lines WL9, (WL12), WL8, (WL10), and WL7. In other words, the first and third terrace portions among the five terrace portions arranged in the X direction are located on the same side in the Z direction with respect to the second terrace portion. The third and fifth terrace portions are located on the same side in the Z direction with respect to the fourth terrace portion.

### 4.2 Manufacturing Method

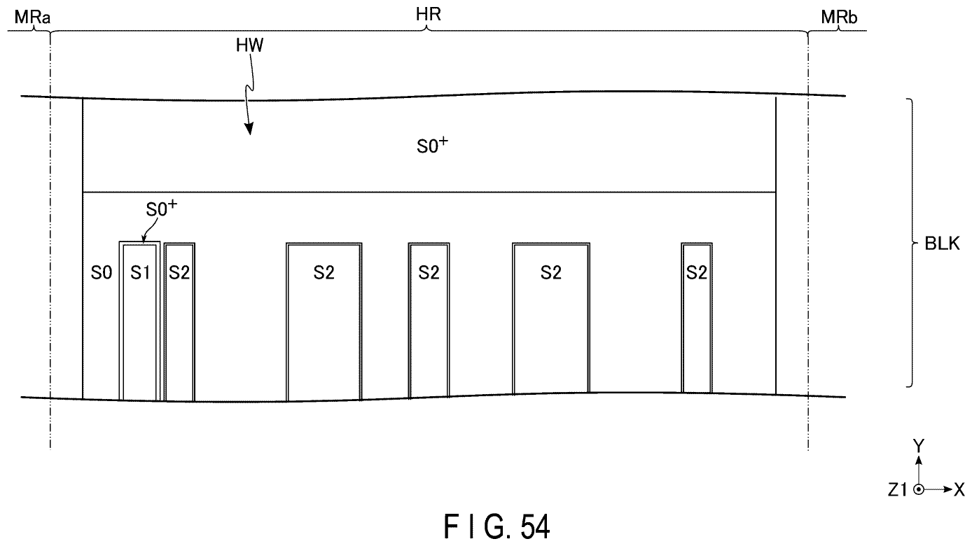

FIGS. 54 to 57 are diagrams illustrating examples of a structure in the process of manufacturing the memory device according to the fourth embodiment. FIGS. 54 to 57 are planar layouts in the process of manufacturing the memory cell array 10 in the memory chip 100, and correspond to FIG. 52.

First, a structure equivalent to that in FIG. 15 in the first embodiment is formed. The region where the terrace portion of the word line WL13 is to be formed forms the region S1, and is made lower in the Z2 direction by one-step height with respect to the region S0.

Next, as illustrated in FIG. 54, the region including the terrace portion of the word line WL12, the region including the terrace portions of the word lines WL9 and WL8, the region including the terrace portion of the word line WL5, the region including the terrace portions of the word lines WL0 and WL1, and the region including the terrace portion of the word line WL4 are etched. Specifically, the insulating layer 35, the uppermost sacrificial layer 63, and the insulating layer 34 and the sacrificial layer 63 for one-step height are removed in each of the region including the terrace portion of the word line WL12, the region including the terrace portions of the word lines WL9 and WL8, the region including the terrace portion of the word line WL5, the region including the terrace portions of the word lines WL0 and WL1, and the region including the terrace portion of the word line WL4. As a result, each of the region including the terrace portion of the word line WL12, the region including the terrace portions of the word lines WL9 and WL8, the region including the terrace portion of the word line WL5, the region including the terrace portions of the word lines WL0 and WL1, and the region including the terrace portion of the word line WL4 forms a region S2, and is made lower in the Z2 direction by two-steps height with respect to the region S0.

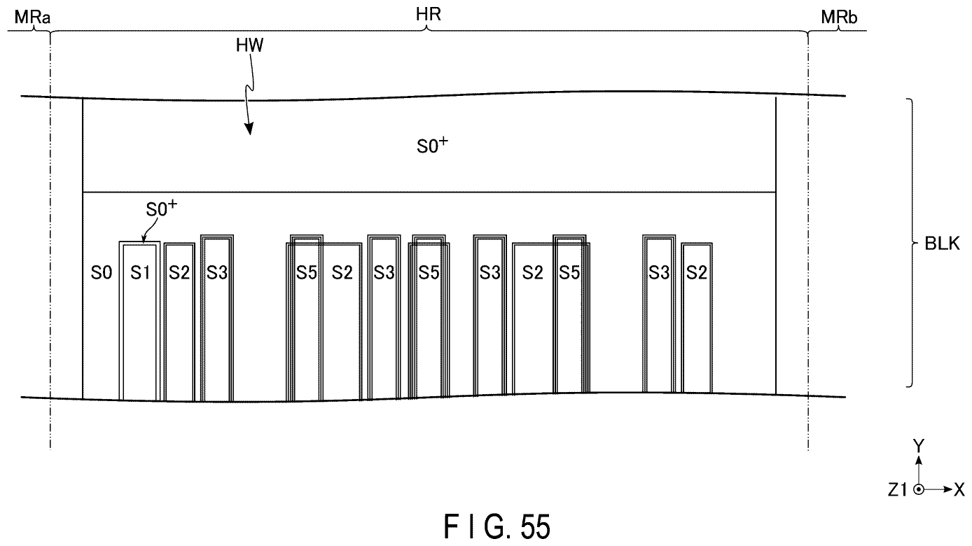

Next, as illustrated in FIG. 55, the region including the terrace portion of the word line WL11, the region including the terrace portion of the word line WL9, the region including the terrace portion of the word line WL7, the region including the terrace portion of the word line WL5, the region including the terrace portion of the select gate line SGS, the region including the terrace portion of the word line WL1, and the region including the terrace portion of the word line WL3 are etched. Specifically, in each of the region including the terrace portion of the word line WL11, the region including the terrace portion of the word line WL9, the region including the terrace portion of the word line WL7, the region including the terrace portion of the word line WL5, the region including the terrace portion of the select gate line SGS, the region including the terrace portion of the word line WL1, and the region including the terrace portion of the word line WL3, the insulating layer 34 and the sacrificial layer 63 for three-steps height (for three-steps height including the uppermost insulating layer 35 in a partial region) are removed. As a result, each of the region including the terrace portion of the word line WL11, the region including the terrace portion of the word line WL7, the region including the terrace portion of the select gate line SGS, and the region including the terrace portion of the word line WL3 forms a region S3, and is made lower in the Z2 direction by three-steps height with respect to the region S0. Each of the region including the terrace portion of the word line WL9, the region including the terrace portion of the word line WL5, and the region including the terrace portion of the word line WL1 forms a region S5, and is made lower in the Z2 direction by five-steps height with respect to the region S0.

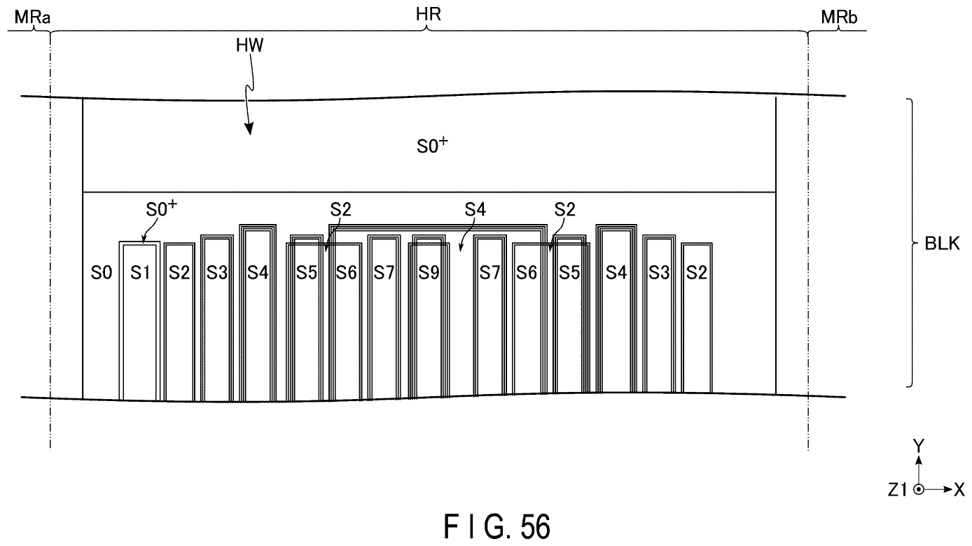

Next, as illustrated in FIG. 56, the region including the terrace portion of the word line WL10, the region including the terrace portions of the word lines WL8, WL7, and WL5, the select gate line SGS, and the word line WL0, and the region including the terrace portion of the word line WL2 are etched. Specifically, in each of the region including the terrace portion of the word line WL10, the region including the terrace portions of the word lines WL8, WL7, and WL5, the select gate line SGS, and the word line WL0, and the region including the terrace portion of the word line WL2, the insulating layer 34 and the sacrificial layer 63 for four-steps height (for four-steps height including the uppermost insulating layer 35 in a partial region) are removed. As a result, each of the region including the terrace portion of the word line WL10 and the region including the terrace portion of the word line WL2 forms a region S4, and is made lower in the Z2 direction by four-steps height with respect to the region S0. Each of the region including the terrace portion of the word line WL8 and the region including the terrace portion of the word line WL0 forms a region S6, and is made lower in the Z2 direction by six-steps height with respect to the region S0. Each of the region including the terrace portion of the word line WL7 and the region including the terrace portion of the select gate line SGS forms a region S7, and is made lower in the Z2 direction by seven-steps height with respect to the region S0. The region including the terrace portion of the word line WL5 forms a region S9, and is made lower in the direction Z2 by nine-steps height with respect to the region S0.

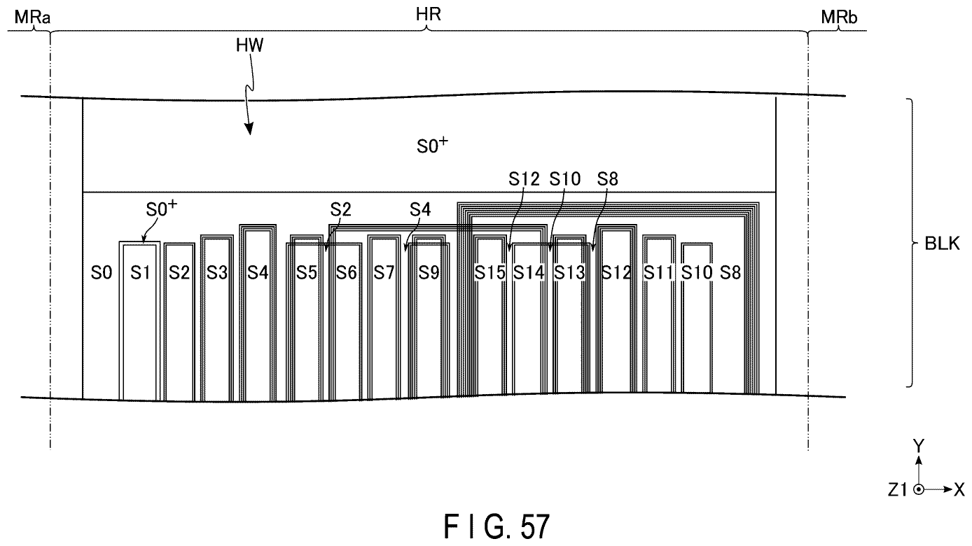

Next, as illustrated in FIG. 57, the region including the terrace portion of the select gate line SGS and the word lines WL0, WL1, WL2, WL3, WL4, and WL6 is etched. Specifically, in the region including the select gate line SGS and the terrace portions of the word lines WL0, WL1, WL2, WL3, WL4, and WL6, the insulating layers 34 and the sacrificial layers 63 for eight-steps height (for eight-steps height including the uppermost insulating layer 35 in a partial region) are removed. As a result, the region including the terrace portion of the select gate line SGS forms a region S15, and is made lower in the Z2 direction by fifteen-steps height with respect to the region S0. The region including the terrace portion of the word line WL0 forms a region S14, and is made lower in the direction Z2 by fourteen-steps height with respect to the region S0. The region including the terrace portion of the word line WL1 forms a region S13, and is made lower in the Z2 direction by thirteen-steps height with respect to the region S0. The region including the terrace portion of the word line WL2 forms a region S12, and is made lower in the Z2 direction by twelve-steps height with respect to the region S0. The region including the terrace portion of the word line WL3 forms a region S11, and is made lower in the Z2 direction by eleven-steps height with respect to the region S0. The region including the terrace portion of the word line WL4 forms a region S10, and is made lower in the Z2 direction by ten-steps height with respect to the region S0. The region including the terrace portion of the word line WL6 forms a region S8, and is made lower in the Z2 direction by eight-steps height with respect to the region S0.

Thereafter, the terrace portion is thickened in the same process as in the first embodiment. As described above, the memory device 3 is formed.

### 4.3 Effects According to Fourth Embodiment

In a case where a steep groove is formed between two adjacent terrace portions where the contact CC is provided, there is a possibility that the insulating layer 37 is not buried in the groove and a void is formed. The conductor can be embedded in the void generated in the groove in the replacement process of the sacrificial layers 62, 63, 64, and 66. The conductor embedding the groove may cause an unintended short circuit between the word lines WL, which is not preferable.

According to the fourth embodiment, in the etching process in the steps, the two etched regions are separated with a margin so as not to overlap each other unless an overlapping region is intentionally formed. As a result, a terrace portion where the contact CC is not provided between the two terrace portions where the contacts CC are provided is formed in a hornlike shape protruding upward from the two terrace portions where the contacts CC are provided. In other words, a groove falling below the two terrace portions is suppressed from being provided between the two terrace portions where the contact CC is provided. Therefore, generation of voids can be suppressed. Therefore, a short circuit between the word lines WL can be suppressed.

Furthermore, between the two terrace portions provided with the contacts CC, the terrace portion not provided with the contact CC is formed in a hornlike shape including at least one lower layer side wiring layer below the wiring layer having the terrace portion. As a result, the regions S3 to S15 can be formed such that the step formed between the terrace portions adjacent to each other (the terrace portion where the contact CC is provided and the terrace portion where the contact CC is not provided) has two or more-steps height. Therefore, in a case where the insulating layer 67 is formed, the film thickness on each step of the regions S0 to S15 can be made significantly thinner than the film thickness on the upper surface of the regions S0 to S15. Therefore, it is easy to leave the sacrificial layer 66 on the upper surface of the regions S0 to S15 while dividing the sacrificial layer 66 by each step, and it is possible to suppress the occurrence of defects due to the process of thickening the wiring layers 22 and 23.

### 5. Modifications and Others

Various modifications can be applied to the first embodiment, the second embodiment, the third embodiment, and the fourth embodiment described above.

### 5.1 Modifications

In the first embodiment, the second embodiment, the third embodiment, and the fourth embodiment described above, the case where the contact CC is formed so as to penetrate one staircase structure has been described, but the present invention is not limited thereto. For example, the contact CC may be formed so as to penetrate a plurality of staircase structures stacked in the Z direction.

FIG. 58 is a cross-sectional view illustrating an example of a cross-sectional structure of a memory cell array included in a memory device according to a modification. FIG. 58 corresponds to FIG. 5 according to the first embodiment.

As illustrated in FIG. 58, a memory cell array 10 is provided with a stacked wiring structure in which a lower layer tier LT and an upper layer tier UT are stacked in this order on the upper surface of an insulating layer 32 in the Z1 direction.

In the lower layer tier LT, an insulating layer 33 and a wiring layer 22 are provided in this order on the upper surface of the insulating layer 32 in the Z1 direction. On the upper surface of the wiring layer 22 in the Z1 direction, 15 sets of insulating layers 34 and wiring layers 23 are stacked. An insulating layer 35 is provided on the upper surface of the uppermost wiring layer 23 in the Z1 direction. The wiring layer 22 corresponds to a select gate line SGS. The 15 wiring layers 23 in the lower layer tier LT correspond to word lines WL0 to WL14, respectively.

In the upper layer tier UT, a wiring layer 23 and 15 sets of insulating layers 34 and wiring layers 23 are stacked on the upper surface of the insulating layer 35 of the lower layer tier LT in the Z1 direction. An insulating layer 35 is provided on the upper surface of the uppermost wiring layer 23 in the Z1 direction. A wiring layer 24 and an insulating layer 36 are provided in this order on the upper surface of the insulating layer 35 of the upper layer tier UT in the Z1 direction. The 16 wiring layers 23 in the upper layer tier UT correspond to word lines WL15 to WL30, respectively. The wiring layer 24 corresponds to a select gate line SGD.

A plurality of memory pillars MP penetrates the above-described stacked wiring structure in memory regions MRa and MRb. Each memory pillar MP includes an upper pillar UP corresponding to the upper layer tier UT and a lower pillar LP corresponding to the lower layer tier LT.

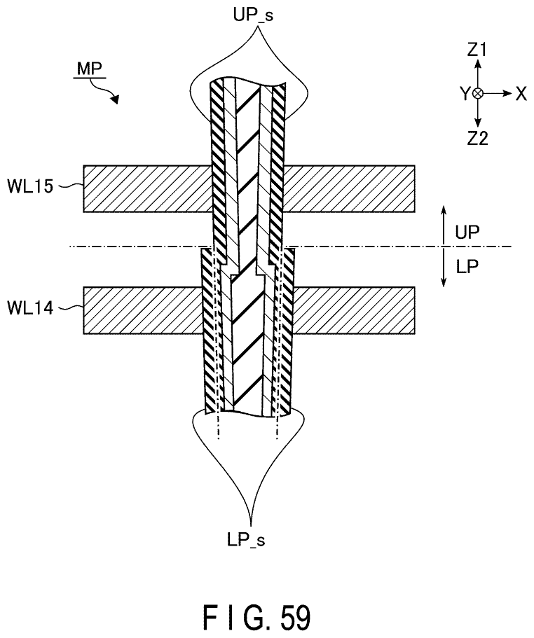

FIG. 59 is a cross-sectional view illustrating an example of a cross-sectional structure in a region LIX of FIG. 58 among the memory pillars included in the memory cell array according to the modification.

As illustrated in FIG. 59, each of the lower pillar LP and the upper pillar UP has a smaller cross-sectional area (XY cross-sectional area) along the XY plane from the upper side to the lower side in the Z1 direction. The XY cross-sectional area of the upper end of the lower pillar LP is larger than the XY cross-sectional area of the lower end of the upper pillar UP. A side surface LP_s of the lower pillar LP and an extension of a side surface UP_s of the upper pillar UP (illustrated by the one-dot chain lines in FIG. 59) are shifted from each other and do not coincide with each other. Such a shift between the side surface LP_s of the lower pillar LP and the extension of the side surface UP_s of the upper pillar UP is generated not only in the YZ cross section illustrated in FIG. 59 but also in any cross section including the Z direction.

Staircase structures provided in a hookup region HR have equivalent configurations in the upper layer tier UT and the lower layer tier LT.

Specifically, in the lower layer tier LT, two wiring layers having two terrace portions adjacent to each other among the select gate line SGS and the word lines WL0 to WL12 are arranged in the Z direction via at least one wiring layer other than the two wiring layers having the two terrace portions adjacent to each other, thereby forming a step with two or more-steps height. The terrace portion of the word line WL13 forms a step with one-step height with the terrace portion of the word line WL14. There is a terrace portion of the word line WL14 between the terrace portion of each of the select gate line SGS and the word lines WL0 to WL12 and the terrace portion of the word line WL13. The height of the step formed between the terrace portion of the wiring layer 23 corresponding to the word line WL14 and the terrace portion of the wiring layer 23 corresponding to the word line WL13 is substantially equal to or more than two-steps height due to the insulating layer 35.

Similarly, in the upper layer tier UT, two wiring layers having two terrace portions adjacent to each other among the word lines WL15 to WL28 are arranged in the Z direction via at least one wiring layer other than the two wiring layers having the two terrace portions adjacent to each other, thereby forming a step with two or more-steps height. The terrace portion of the word line WL29 forms one step with the terrace portion of the word line WL30. There is a terrace portion of the word line WL30 between the terrace portion of each of the word lines WL15 to WL28 and the terrace portion of the word line WL29. The height of the step formed between the terrace portion of the wiring layer 23 corresponding to the word line WL30 and the terrace portion of the wiring layer 23 corresponding to the word line WL29 is substantially equal to or more than two-steps height due to the insulating layer 35.

The above-described configuration is realized by repeatedly applying the manufacturing process of the staircase structure described in the first embodiment to the manufacturing process of the staircase structure in the lower layer tier LT and the manufacturing process of the staircase structure in the upper layer tier UT. As a result, even in the configuration according to the modification, it is possible to suppress the occurrence of defects due to the thickening process of the wiring layers 22 and 23.

### 5.2 Others

In the first embodiment, the second embodiment, and the fourth embodiment described above, the case where the number of terrace portions adjacent to only the terrace portion of the uppermost layer is one has been described. In the third embodiment, the case where there are two terrace portions adjacent to only the terrace portion of the uppermost layer has been described. Not limited to the examples of the first embodiment, the second embodiment, the third embodiment, and the fourth embodiment described above, for example, the number of terrace portions adjacent to only the terrace portion of the uppermost layer may be A (A is an integer that is equal to or greater than one). In this case, the terrace portions of the (2A+2) wiring layers continuous from the uppermost layer toward the semiconductor layer 21 are arranged adjacent to the terrace portion of the uppermost layer.

In addition, in the first embodiment, the second embodiment, and the fourth embodiment described above, the case where the regions S2 to S15 are formed by executing the etching processes for two-steps height, three-steps height, four-steps height, and eight-steps height on the region S0 has been described, but the present invention is not limited thereto. By adding etching processes of increasing the height by two times such as sixteen-steps height, thirty two-steps height, . . . after the etching process for eight-steps height, it is possible to form more regions such that the steps formed between the regions adjacent to each other have two or more-steps height.

In the third embodiment described above, the case where the etching processes for three-steps height, four-steps height, five-steps height, six-steps height, and twelve-steps height are performed in the region S0 to form the regions S2 to S15 has been described, but the present invention is not limited thereto. By adding an etching processes of increasing the height by two times such as twenty four-steps height, forty eight-steps height, . . . after the etching process for twelve-steps height, it is possible to form more regions such that the steps formed between the regions adjacent to each other have two or more-steps height.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A memory device comprising:
a plurality of first wiring layers that are aligned apart from each other in a first direction;
a second wiring layer, a third wiring layer, and a fourth wiring layer that are aligned in the first direction apart from the first wiring layers and are aligned in this order and apart from each other in the first direction without interposing another wiring layer; and
a first memory pillar that extends in the first direction and includes portions respectively intersecting with the first wiring layers, the second wiring layer, and the third wiring layer to function as memory cells, wherein the first wiring layers, the second wiring layer, and the third wiring layer include a plurality of first terrace portions, a second terrace portion, and a third terrace portion, respectively, that are thickened,
between each of the first terrace portions and each of a plurality of other first terrace portions adjacent to the each of the first terrace portions as viewed in the first direction, at least one wiring layer other than two wiring layers having two adjacent first terrace portions is provided,
the third terrace portion is adjacent to the second terrace portion as viewed in the first direction, and
the third wiring layer includes a portion that is not thickened, at a boundary between the third terrace portion and the second terrace portion.

2. The memory device according to claim 1, wherein
each of the first terrace portions is aligned with the second terrace portion via the third terrace portion as viewed in the first direction.

3. The memory device according to claim 1, wherein
a distance between the third wiring layer and the fourth wiring layer is greater than a distance between two wiring layers adjacent to each other among the first wiring layers, the second wiring layer, and the third wiring layer.

4. The memory device according to claim 1, further comprising
a first member and a second member each extending in a second direction that intersects the first direction, the first member and the second member sandwiching the first wiring layers, the second wiring layer, the third wiring layer, and the fourth wiring layer in a third direction that intersects the first direction and the second direction, wherein
the first terrace portions are aligned in the second direction.

5. The memory device according to claim 1, further comprising
a first member and a second member each extending in a second direction that intersects the first direction, the first member and the second member sandwiching the first wiring layers, the second wiring layer, the third wiring layer, and the fourth wiring layer in a third direction that intersects the first direction and the second direction, wherein
the first terrace portions are classified into a plurality of fourth terrace portions and a plurality of fifth terrace portions,
the fourth terrace portions are aligned side by side with the fifth terrace portions in the third direction,
the fourth terrace portions are aligned in the second direction, and
the fifth terrace portions are aligned in the second direction.

6. The memory device according to claim 1, further comprising
a fifth wiring layer positioned between the first wiring layers and the second wiring layer and aligned with the second wiring layer in the first direction without interposing another wiring layer, wherein
the fifth wiring layer includes a thickened sixth terrace portion,
between each of the first terrace portions and each of a plurality of other first terrace portions adjacent to the each of the first terrace portions as viewed in the first direction, at least two wiring layers other than two wiring layers having two adjacent first terrace portions are provided,
the third terrace portion is adjacent to the sixth terrace portion as viewed in the first direction, and
the third wiring layer includes a portion that is not thickened, at a boundary between the third terrace portion and the sixth terrace portion.

7. The memory device according to claim 6, wherein
each of the first terrace portions is aligned with the sixth terrace portion via the third terrace portion as viewed in the first direction.

8. The memory device according to claim 1, wherein
the first memory pillar includes a first portion and a second portion aligned in the first direction, and
an extension of a side surface of the first portion and a side surface of the second portion are shifted from each other.

9. The memory device according to claim 1, further comprising:
a plurality of first contacts extending in the first direction and being in contact with respective first terrace portions;
a second contact extending in the first direction and being in contact with the second terrace portion; and
a third contact extending in the first direction and being in contact with the third terrace portion.

10. The memory device according to claim 9, wherein
each of the first contacts, the second contact, and the third contact intersects with the first wiring layers.

11. The memory device according to claim 1, further comprising:
a first member and a second member each extending in a second direction that intersects the first direction, the first member and the second member sandwiching the first wiring layers, the second wiring layer, the third wiring layer, and the fourth wiring layer in a third direction that intersects the first direction and the second direction; and
a second memory pillar that extends in the first direction, is located on a side opposite to the first memory pillar with respect to the first terrace portions, the second terrace portion, and the third terrace portion, and includes portions respectively intersecting with the first wiring layers, the second wiring layer, and the third wiring layer to function as memory cells.

12. The memory device according to claim 11, wherein
each of the first wiring layers, the second wiring layer, and the third wiring layer includes a first layer portion on a side of the first memory pillar and a second layer portion on a side of the second memory pillar, the first layer portion and the second layer portion being continuous in a region sandwiched between the first member and the second member, and
the fourth wiring layer includes a third layer portion on the side of the first memory pillar and a fourth layer portion on the side of the second memory pillar, the third layer portion and the fourth layer portion being separated in the region sandwiched between the first member and the second member.

13. A memory device comprising:
a plurality of wiring layers that are aligned apart from each other in a first direction, the wiring layers including a first wiring layer including a first terrace portion, a second wiring layer including a second terrace portion, a third wiring layer including a third terrace portion, a fourth wiring layer including a fourth terrace portion, and a fifth wiring layer including a fifth terrace portion; and
a first memory pillar that extends in the first direction and includes portions respectively intersecting with the first wiring layer, the second wiring layer, the third wiring layer, the fourth wiring layer, and the fifth wiring layer to function as memory cells, wherein
the first terrace portion, the second terrace portion, the third terrace portion, the fourth terrace portion, and the fifth terrace portion are adjacent in this order in a second direction that intersects the first direction as viewed in the first direction,
the first wiring layer and the third wiring layer are located on a same side in the first direction with respect to the second wiring layer,
the third wiring layer and the fifth wiring layer are located on the same side in the first direction with respect to the fourth wiring layer, and
at least one wiring layer is present each of between the first wiring layer and the second wiring layer, between the second wiring layer and the third wiring layer, between the third wiring layer and the fourth wiring layer, and between the fourth wiring layer and the fifth wiring layer.

14. The memory device according to claim 13, further comprising:
a first contact extending in the first direction and being in contact with the first terrace portion;
a second contact extending in the first direction and being in contact with the second terrace portion;
a third contact extending in the first direction and being in contact with the third terrace portion;
a fourth contact extending in the first direction and being in contact with the fourth terrace portion; and
a fifth contact extending in the first direction and being in contact with the fifth terrace portion.

15. The memory device according to claim 13, further comprising:
a first contact extending in the first direction and being in contact with the first terrace portion;
a third contact extending in the first direction and being in contact with the third terrace portion; and
a fifth contact extending in the first direction and being in contact with the fifth terrace portion, wherein
the second terrace portion and the fourth terrace portion are provided on different wiring layers.

16. The memory device according to claim 15, wherein
each of the first contact, the third contact, and the fifth contact intersects with the first wiring layer, the third wiring layer, and the fifth wiring layer.

17. The memory device according to claim 13, wherein
the third wiring layer is adjacent to the first wiring layer and the fifth wiring layer in the first direction.

18. A memory device, comprising:
a plurality of wiring layers that are aligned apart from each other in a first direction, the wiring layers including a first wiring layer including a first terrace portion, a second wiring layer including a second terrace portion, a third wiring layer including a third terrace portion, and a fourth wiring layer including a fourth terrace portion;
a first memory pillar that extends in the first direction and includes portions respectively intersecting with the first wiring layer, the second wiring layer, the third wiring layer, and the fourth wiring layer to function as memory cells;
a first contact extending in the first direction and being in contact with the first terrace portion;
a second contact extending in the first direction and being in contact with the second terrace portion;
a third contact extending in the first direction and being in contact with the third terrace portion; and
a fourth contact extending in the first direction and being in contact with the fourth terrace portion, wherein the first terrace portion is adjacent to each of the second terrace portion, the third terrace portion, and the fourth terrace portion as viewed in the first direction, and
the second terrace portion, the third terrace portion, and the fourth terrace portion are located on a same side in the first direction with respect to the first terrace portion.

19. The memory device according to claim 18, wherein
the second terrace portion and the third terrace portion sandwich the first terrace portion in a second direction that intersects the first direction, and
the fourth terrace portion is aligned with the first terrace portion in a third direction that intersects the first direction and the second direction.

20. The memory device according to claim 19, wherein
the wiring layers further includes a fifth wiring layer including a fifth terrace portion,
the fourth terrace portion and the fifth terrace portion sandwich the first terrace portion in the third direction, and
the fifth terrace portion is located on a side opposite to the second terrace portion, the third terrace portion, and the fourth terrace portion in the first direction with respect to the first terrace portion.
